(19) United States
(12) Patent Application Publication
(10) Pub. No.: US 2025/0120120 A1
(43) Pub. Date: Apr. 10, 2025

(54) SILICON CARBIDE SEMICONDUCTOR DEVICE AND METHOD OF MANUFACTURING THEREOF

(71) Applicant: FUJI ELECTRIC CO., LTD., Kawasaki-shi (JP)

(72) Inventor: Syunki NARITA, Matsumoto-city (JP)

(73) Assignee: FUJI ELECTRIC CO., LTD., Kawasaki-shi (JP)

(21) Appl. No.: 18/887,636

(22) Filed: Sep. 17, 2024

(30) Foreign Application Priority Data
Oct. 4, 2023 (JP) 2023-173266

(51) Int. Cl. H01L 29/78; H01L 29/06; H01L 29/16

(52) U.S. Cl. CPC H10D 30/668; H10D 30/611; H10D 62/124; H10D 62/8325

(57) ABSTRACT

A silicon carbide semiconductor device, including: a semiconductor substrate; a first semiconductor region, a plurality of second semiconductor regions, a plurality of third semiconductor regions, and a plurality of fourth semiconductor regions formed in the semiconductor substrate; a plurality of gate trenches penetrating through the second to fourth semiconductor regions, to reach the first semiconductor region; a plurality of first high concentration regions facing bottoms of the plurality of gate trenches. Each second semiconductor region is formed between adjacent two of the gate trenches. The silicon carbide semiconductor device has a double-gate structure in which a channel is formed over an entire area of each second semiconductor region, and is sandwiched by adjacent two of the gate trenches. Each first high concentration region has a width that is no more than a width of each gate trench, but is more than a distance between adjacent two of the gate trenches.

### CROSS REFERENCE TO RELATED APPLICATIONS

This application is based upon and claims the benefit of priority of the prior Japanese Patent Application No. 2023-173266, filed on Oct. 4, 2023, the entire contents of which are incorporated herein by reference.

### BACKGROUND OF THE INVENTION

### 1. Field of the Invention

Embodiments of the invention relate to a silicon carbide semiconductor device and a method of manufacturing a silicon semiconductor device.

### 2. Description of the Related Art

F. Udrea, et al., “Experimental Demonstration, Challenges, and Prospects of the Vertical SiC FinFET”, 2022 IEEE 34th ISPSD, May 2022 and patent publication of Japanese Patent No. 6631632 describe a vertical SiC-metal oxide semiconductor field effect transistor (MOSFET) (a MOS type field effect transistor with an insulated gate having a three-layer structure of metal-oxide-semiconductor) having a trench gate structure in which a unit cell (functional unit of a device) of a FinFET structure is disposed. Japanese Laid-Open Patent Publication No. 2022-010335 and Japanese Laid-Open Patent Publication No. 2021-012934 describe a trench gate structure in which a p-type region for relaxing an electric field is disposed at a bottom of a gate trench.

### SUMMARY OF THE INVENTION

According to an embodiment of the present disclosure, a silicon carbide semiconductor device includes: a semiconductor substrate containing silicon carbide and having a first main surface and a second main surface opposite to each other; a first semiconductor region of a first conductivity type, provided in the semiconductor substrate; a plurality of second semiconductor regions of a second conductivity type, provided in the semiconductor substrate between the first main surface of the semiconductor substrate and the first semiconductor region; a plurality of third semiconductor regions of the first conductivity type, selectively provided in the semiconductor substrate between the first main surface of the semiconductor substrate and the plurality of second semiconductor regions; a plurality of fourth semiconductor regions of the second conductivity type, selectively provided in the semiconductor substrate between the first main surface of the semiconductor substrate and the plurality of second semiconductor regions, the plurality of fourth semiconductor regions having a dopant concentration higher than a dopant concentration of the plurality of second semiconductor regions; a plurality of gate trenches penetrating through the plurality of fourth semiconductor regions, the plurality of third semiconductor regions, and the plurality of second semiconductor regions, each of the plurality of gate trenches reaching the first semiconductor region; a plurality of first high concentration regions of the second conductivity type, provided at positions facing bottoms of the plurality of gate trenches, the plurality of first high concentration regions having a dopant concentration higher than the dopant concentration of the plurality of second semiconductor regions; a plurality of gate electrodes disposed in the plurality of gate trenches via a plurality of gate insulating films, respectively; a first electrode electrically connected to the plurality of fourth semiconductor regions, the plurality of third semiconductor regions, the plurality of second semiconductor regions, and the plurality of first high concentration regions; and a second electrode disposed on the second main surface of the semiconductor substrate. The plurality of gate trenches have, between any adjacent two thereof, one of the plurality of second semiconductor regions formed therein. The silicon carbide semiconductor device has a double-gate structure in which, for each adjacent two of the plurality of gate trenches, a channel is formed over an entire area of the second semiconductor region therebetween, and is sandwiched from two sides thereof by said each adjacent two of the plurality of gate trenches. Each of the plurality of first high concentration regions has a width that is no more than a width of each of the plurality of gate trenches, but is more than a distance between any adjacent two of the plurality of gate trenches.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a plan view depicting a layout of a silicon carbide semiconductor device according to a first embodiment, as viewed from a front surface of a semiconductor substrate thereof.

FIG. 2 is a cross-sectional view depicting a structure along cutting line A-A′ in FIG. 1.

FIG. 3 is a cross-sectional view depicting the structure along cutting line B-B′ in FIG. 1.

FIG. 4 is a cross-sectional view depicting a structure of a silicon carbide semiconductor device according to a second embodiment.

FIG. 5 is a cross-sectional view depicting a structure of a silicon carbide semiconductor device according to a third embodiment.

FIG. 6 is a cross-sectional view depicting the structure of the silicon carbide semiconductor device according to the third embodiment.

FIG. 7A is a cross-sectional view depicting a state during manufacture of the silicon carbide semiconductor device according to the third embodiment.

FIG. 7B is a cross-sectional view depicting a state during the manufacture of the silicon carbide semiconductor device according to the third embodiment.

FIG. 8A is a cross-sectional view depicting a state during the manufacture of the silicon carbide semiconductor device according to the third embodiment.

FIG. 8B is a cross-sectional view depicting a state during the manufacture of the silicon carbide semiconductor device according to the third embodiment.

FIG. 9A is a cross-sectional view depicting a state during the manufacture of the silicon carbide semiconductor device according to the third embodiment.

FIG. 9B is a cross-sectional view depicting a state during the manufacture of the silicon carbide semiconductor device according to the third embodiment.

FIG. 10A is a cross-sectional view depicting a state during the manufacture of the silicon carbide semiconductor device according to the third embodiment.

FIG. 10B is a cross-sectional view depicting a state during the manufacture of the silicon carbide semiconductor device according to the third embodiment.

FIG. 11A is a cross-sectional view depicting a state during manufacture of a silicon carbide semiconductor device according to a fourth embodiment.

FIG. 11B is a cross-sectional view depicting a state during the manufacture of the silicon carbide semiconductor device according to the fourth embodiment.

FIG. 12A is a cross-sectional view depicting a state during the manufacture of the silicon carbide semiconductor device according to the fourth embodiment.

FIG. 12B is a cross-sectional view depicting a state during the manufacture of the silicon carbide semiconductor device according to the fourth embodiment.

FIG. 13A is a cross-sectional view depicting a state during the manufacture of the silicon carbide semiconductor device according to the fourth embodiment.

FIG. 13B is a cross-sectional view depicting a state during the manufacture of the silicon carbide semiconductor device according to the fourth embodiment.

FIG. 14A is a cross-sectional view depicting a state during the manufacture of the silicon carbide semiconductor device according to the fourth embodiment.

FIG. 14B is a cross-sectional view depicting a state during the manufacture of the silicon carbide semiconductor device according to the fourth embodiment.

FIG. 15 is a cross-sectional view depicting a structure of a silicon carbide semiconductor device according to a fifth embodiment.

FIG. 16 is a cross-sectional view depicting a structure in a vicinity of gate trenches of a first comparison example.

FIG. 17 is a cross-sectional view depicting a structure in a vicinity of gate trenches of a second comparison example.

FIG. 18 is a characteristic diagram depicting results of simulation of a relationship between TBP width W_TBP and trench width W_Trench of the first and second comparison examples.

FIG. 19 is a characteristic diagram depicting results of simulation of the relationship between TBP width W_TBP and trench width W_Trench of the first and second comparison examples.

FIG. 20 is a characteristic diagram depicting results of simulation of the relationship between TBP width W_TBP and trench width W_Trench of the first and second comparison examples.

FIG. 21 is a characteristic diagram depicting results of simulation of the relationship between TBP width W_TBP and trench width W_Trench of the first and second comparison examples.

FIG. 22 is a plan view depicting a layout of a silicon carbide semiconductor device of a reference example as viewed from a front surface of a semiconductor substrate thereof.

FIG. 23 is a cross-sectional view depicting a structure along cutting line AA-AA′ in FIG. 22.

FIG. 24 is a cross-sectional view depicting the structure along cutting line BB-BB′ in FIG. 22.

### DETAILED DESCRIPTION OF THE INVENTION

First, problems associated with the conventional techniques is discussed. In F. Udrea, et al. and Japanese Laid-Open Patent Publication No. 6631632, a Fin width (the width between adjacent gate trenches) is narrow and thus, the electric field strength at the bottom of the gate trench becomes large when the device is off and the electric field concentrates in the gate insulating film at the bottom of the gate trench, resulting in a problem of a low breakdown voltage.

An outline of the disclosure is described. (1) A silicon carbide semiconductor device according to one aspect of the disclosure is as follows. A first semiconductor region of a first conductivity type is provided in a semiconductor substrate containing silicon carbide. A plurality of second semiconductor regions of a second conductivity type is provided between a first main surface of the semiconductor substrate and the first semiconductor region. A plurality of third semiconductor regions of the first conductivity type is selectively provided between the first main surface of the semiconductor substrate and the plurality of second semiconductor regions. A plurality of fourth semiconductor regions of the second conductivity type is selectively provided between the first main surface of the semiconductor substrate and the plurality of second semiconductor regions. The plurality of fourth semiconductor regions has a higher dopant concentration than a dopant concentration of the plurality of second semiconductor regions. A plurality of gate trenches penetrates through the plurality of fourth semiconductor regions, the plurality of third semiconductor regions, and the plurality of second semiconductor regions and reaches the first semiconductor region.

A plurality of first high concentration regions of the second conductivity type is provided at positions facing bottoms of the plurality of gate trenches. The plurality of first high concentration regions has a higher dopant concentration than the dopant concentration of the plurality of second semiconductor regions. A plurality of gate electrodes is provided in the plurality of gate trenches via a plurality of gate insulating films, respectively. A first electrode is electrically connected to the plurality of fourth semiconductor regions, the plurality of third semiconductor regions, the plurality of second semiconductor regions, and the plurality of first high concentration regions. A second electrode is disposed on a second main surface of the semiconductor substrate. A double-gate structure in which one channel sandwiched from both sides thereof by any adjacent two of the plurality of gate trenches is formed in an entire area of a corresponding one of the plurality of second semiconductor regions between the any adjacent two of the plurality of gate trenches. A width of each of the plurality of first high concentration regions is not more than a width of each of the plurality of gate trenches but is wider than a distance between the any adjacent two of the plurality of gate trenches.

According to the disclosure described above, the gate insulating films along the bottoms of the plurality of gate trenches is protected by the plurality of first high concentration regions and electric field applied to the gate insulating films along the bottoms of the plurality of gate trenches is relaxed, thereby enabling improvement of the breakdown voltage. The width of each of the plurality of first high concentration regions is not more than the width of the gate trench, whereby increases in on-resistance due to JFET resistance may be suppressed.

(2) In the silicon carbide semiconductor device according to the present disclosure, in (1) described above, the width of each of the plurality of first high concentration regions may be set to be not less than 75% of the width of the each of the plurality of gate trenches.

According to the disclosure described above, electric field applied to the gate insulating films along the bottoms of the plurality of gate trenches may be made to be 3 MV/cm or less.

(3) In the silicon carbide semiconductor device according to the disclosure, in (1) or (2) described above, a depth of the plurality of first high concentration regions may be at least equal to the distance between the any adjacent two of the plurality of gate trenches.

According to the disclosure described above, an effect of the double gate structure (reduced on-resistance) may be obtained and further, a predetermined breakdown voltage is ensured, thereby enabling the predetermined breakdown voltage to be obtained.

(4) In the silicon carbide semiconductor device according to the disclosure, in any one of (1) to (3) described above, the depth of the plurality of first high concentration regions may be 0.8 μm or more.

According to the disclosure described above, the effect of the double gate structure may be obtained and further, a predetermined breakdown voltage may be ensured, thereby enabling the predetermined breakdown voltage to be obtained.

(5) In any one of (1) to (4) described above, in the silicon carbide semiconductor device according to the disclosure, the plurality of gate trenches extends linearly in a first direction parallel to the first main surface of the semiconductor substrate. The plurality of third semiconductor regions and the plurality of fourth semiconductor regions may be provided between the any adjacent two of the plurality of gate trenches and may repeatedly alternate with one another in the first direction.

According to the above disclosure, the distance between the any adjacent two of the plurality of gate trenches may be reduced by a predetermined amount to form the double gate structure.

(6) In (5) described above, the silicon carbide semiconductor device according to the disclosure includes a plurality of second high concentration regions of the second conductivity type, selectively provided between the any adjacent two of the plurality of gate trenches, the plurality of second high concentration regions being in contact with the plurality of second semiconductor regions and facing the plurality of fourth semiconductor regions in the depth direction, the plurality of second high concentration regions having a higher dopant concentration than the dopant concentration of the plurality of second semiconductor regions. The plurality of first high concentration regions may be electrically connected to the plurality of second semiconductor regions via the plurality of second high concentration regions.

According to the above disclosure, the plurality of first high concentration regions is electrically connected to the plurality of second semiconductor regions via the plurality of second high concentration regions, whereby the width of each of the plurality of first high concentration regions may be set to be not more than the width of each of the plurality of gate trenches.

(7) In the silicon carbide semiconductor device according to the disclosure, in (6) above, of the plurality of first high concentration regions, ones adjacent to one another in a second direction parallel to the first main surface of the semiconductor substrate and orthogonal to the first direction are partially connected to each other at locations facing the plurality of second high concentration regions in the depth direction. The plurality of second high concentration regions may be in contact with the plurality of first high concentration regions in the depth direction.

According to the disclosure described above, except for a portion connected to an adjacent one plurality of first high concentration regions, the width of the plurality of first high concentration regions may be set to be not more than the width of each of the gate trenches.

(8) In the silicon carbide semiconductor device according to the disclosure, in (6) above, the plurality of second high concentration regions may reach a depth closer to the second electrode than are the bottoms of the plurality of gate trenches and be in contact with the plurality of first high concentration regions in a second direction parallel to the first main surface of the semiconductor substrate and orthogonal to the first direction.

According to the disclosure described above, the width of the plurality of first high concentration regions may be set to be not more than the width of the gate trench overall.

An outline of the disclosure is described. (9) A silicon carbide semiconductor device according to one aspect of the disclosure is as follows. A first semiconductor region of a first conductivity type is provided in a semiconductor substrate containing silicon carbide. A plurality of second semiconductor regions of a second conductivity type is provided between a first main surface of the semiconductor substrate and the first semiconductor region. A plurality of third semiconductor regions of the first conductivity type is selectively provided between the first main surface of the semiconductor substrate and the plurality of second semiconductor regions. A plurality of fourth semiconductor regions of the second conductivity type is selectively provided between the first main surface of the semiconductor substrate and the plurality of second semiconductor regions. The plurality of fourth semiconductor regions has a higher dopant concentration than a dopant concentration of the plurality of second semiconductor regions.

A plurality of gate trenches penetrates through the plurality of fourth semiconductor regions, the plurality of third semiconductor regions, and the plurality of second semiconductor regions and reaches the first semiconductor region. A plurality of first high concentration regions of the second conductivity type is provided at positions facing bottoms of the plurality of gate trenches. The plurality of first high concentration regions has a higher dopant concentration than the dopant concentration of the plurality of second semiconductor regions. A plurality of second high concentration regions of the second conductivity type is selectively provided between any adjacent two of the plurality of gate trenches and is in contact with the plurality of second semiconductor regions. The plurality of second high concentration regions has a higher dopant concentration than the dopant concentration of the plurality of second semiconductor regions. A plurality of gate electrodes is disposed in the plurality of gate trenches via a plurality of gate insulating films, respectively. A first electrode is electrically connected to the plurality of fourth semiconductor regions, the plurality of third semiconductor regions, the plurality of second semiconductor regions, the plurality of first high concentration regions, and the plurality of second high concentration regions.

A second electrode is provided on a second main surface of the semiconductor substrate. A double-gate structure in which one channel sandwiched from both sides thereof by the any adjacent two of the gate trenches is formed over an entire area of a corresponding one of the plurality of second semiconductor regions, the corresponding one being between the any adjacent two of the plurality of gate trenches. The plurality of gate trenches extends linearly in the first direction parallel to the first main surface of the semiconductor substrate. The plurality of third semiconductor regions and the plurality of fourth semiconductor regions are provided between the any adjacent two of the plurality of gate trenches and repeatedly alternate with one another in the first direction. The plurality of second high concentration regions is disposed facing the plurality of fourth semiconductor regions in the depth direction. The plurality of first high concentration regions is electrically connected to the plurality of second semiconductor regions via the plurality of second high concentration regions.

According to the disclosure described above, the plurality of first high concentration regions protects the gate insulating film along the bottoms of the plurality of gate trenches, and electric field applied to the gate insulating film along the bottoms of the plurality of gate trenches is relaxed, thereby improving the breakdown voltage. The plurality of first high concentration regions are electrically connected to the plurality of second semiconductor regions via the plurality of second high concentration regions, and the width of the plurality of first high concentration regions may be set to not be more than the width of each of the gate trenches. The width of the plurality of first high concentration regions is not more than the width of the gate trenches, whereby increases in on-resistance due to JFET resistance may be suppressed.

(10) In the silicon carbide semiconductor device according to the disclosure, in any one of (1) to (5) above, each of the plurality of first high concentration regions may have a portion facing a corresponding one of the plurality of fourth semiconductor regions in the depth direction, the portion extending along a sidewall of one of the any adjacent two of the plurality of gate trenches in a direction to the first electrode and being in contact with the corresponding one of the plurality of second semiconductor regions.

According to the above disclosure, the plurality of first high concentration regions may be directly connected to the plurality of second semiconductor regions. Carrier spreading resistance is reduced by not providing the plurality of second high concentration regions.

An outline of the disclosure is described. (11) A silicon carbide semiconductor device according to one aspect of the disclosure is as follows. A first semiconductor region of a first conductivity type is provided in a semiconductor substrate containing silicon carbide. A plurality of second semiconductor regions of a second conductivity type is provided between a first main surface of the semiconductor substrate and the first semiconductor region. A plurality of third semiconductor regions of the first conductivity type is selectively provided between the first main surface of the semiconductor substrate and the plurality of second semiconductor regions. A plurality of fourth semiconductor regions of the second conductivity type is selectively provided between the first main surface of the semiconductor substrate and the plurality of second semiconductor regions. The plurality of fourth semiconductor regions has a higher dopant concentration than a dopant concentration of the plurality of second semiconductor regions. A plurality of gate trenches penetrates through the plurality of fourth semiconductor regions, the plurality of third semiconductor regions, and the plurality of second semiconductor regions and reaches the first semiconductor region. A plurality of first high concentration regions of the second conductivity type is selectively provided at positions facing bottoms of the plurality of gate trenches. The plurality of first high concentration regions has a dopant concentration higher than the dopant concentration of the plurality of second semiconductor regions

A plurality of gate electrodes is disposed in the plurality of gate trenches via a plurality of gate insulating films, respectively. A first electrode is electrically connected to the plurality of fourth semiconductor regions, the plurality of third semiconductor regions, the plurality of second semiconductor regions, and the plurality of first high concentration regions. A second electrode is disposed on a second main surface of the semiconductor substrate. A double-gate structure in which one channel sandwiched from both sides thereof by any adjacent two of the plurality of gate trenches is formed over an entire area of a corresponding one of the plurality of second semiconductor regions, the corresponding one being between the any adjacent two of the plurality of gate trenches. The plurality of gate trenches extends linearly in the first direction parallel to the first main surface of the semiconductor substrate. The plurality of third semiconductor regions and the plurality of fourth semiconductor regions are disposed between the any adjacent two of the plurality of gate trenches and repeatedly alternative with one another in the first direction. Each of the plurality of first high concentration regions has a portion facing a corresponding one of the plurality of fourth semiconductor regions in the depth direction, the portion extending along a sidewall of one of the any adjacent two of the plurality of gate trenches in a direction to the first electrode and being in contact with the corresponding one of the plurality of second semiconductor regions.

According to the above disclosure, the plurality of first high concentration regions may be directly connected to the plurality of second semiconductor regions. Carrier spreading resistance is reduced by not providing the plurality of second high concentration regions.

(12) In the silicon carbide semiconductor device according to the disclosure, in any one of (6) to (11) described above, the plurality of first high concentration regions may not be disposed at positions facing the plurality of third semiconductor regions in the depth direction.

According to the above disclosure, increases in JFET resistance may be suppressed.

(13) In the silicon carbide semiconductor device according to the disclosure, in any one of (6) to (9) above, the plurality of second high concentration regions may not be disposed at positions facing the plurality of third semiconductor regions in the depth direction.

According to the disclosure above, increases in the JFET resistance may be suppressed.

(14) The silicon carbide semiconductor device according to the present disclosure, in (1), (9), or (11) above, may include a fifth semiconductor region of the first conductivity type, provided between and in contact with the first semiconductor region and the plurality of second semiconductor regions, the fifth semiconductor region terminating at a depth in a direction to the second electrode equal to a depth of the plurality of first high concentration regions, the fifth semiconductor region having a dopant concentration higher than a dopant concentration of the first semiconductor region.

According to the disclosure described above, carrier spreading resistance may be reduced.

An outline of the disclosure is described. (15) A silicon carbide semiconductor device according to one aspect of the disclosure is as follows. A first semiconductor region of a first conductivity type is provided in a semiconductor substrate containing silicon carbide. A plurality of second semiconductor regions of a second conductivity type is provided between a first main surface of the semiconductor substrate and the first semiconductor region. A plurality of third semiconductor regions of the first conductivity type is selectively provided between the first main surface of the semiconductor substrate and the plurality of second semiconductor regions. A plurality of fourth semiconductor regions of the second conductivity type is selectively provided between the first main surface of the semiconductor substrate and the plurality of second semiconductor regions. The plurality of fourth semiconductor regions has a higher dopant concentration than a dopant concentration of the plurality of second semiconductor regions. A plurality of gate trenches penetrates through the plurality of fourth semiconductor regions, the plurality of third semiconductor regions, and the plurality of second semiconductor regions and reaches the first semiconductor region.

A plurality of gate insulating films is disposed along inner walls of the plurality of gate trenches. A plurality of gate electrodes is disposed in the plurality of gate trenches, on the plurality of gate insulating films, respectively. A first electrode is electrically connected to the plurality of fourth semiconductor regions, the plurality of third semiconductor regions, and the plurality of second semiconductor regions. A second electrode is disposed on the second main surface of the semiconductor substrate. A double-gate structure in which one channel sandwiched from both sides thereof by any adjacent two of the plurality of gate trenches is formed over an entire area of a corresponding one of the plurality of second semiconductor regions, the corresponding one being between the any adjacent two of the plurality of gate trenches. Any one of the plurality of gate insulating films of any one of the plurality of gate trenches has a first portion of a first thickness at a bottom of the any one of the plurality of gate trenches and a second portion of a second thickness along a sidewall of the any one of the plurality of gate trenches, the first thickness being greater than the second thickness and greater than a distance between the any adjacent two of the plurality of gate trenches.

According to the above disclosure, since the breakdown voltage of the gate insulating film is increased, the gate insulating films along the bottoms of the gate trenches may be protected without providing the first and second high concentration regions, and the breakdown voltage may be improved. By not providing the first and second high concentration regions, the carrier spreading resistance is reduced.

(16) The silicon carbide semiconductor device according to the disclosure, in (15) above, may include a fifth semiconductor region of the first conductivity type, provided between and in contact with the first semiconductor region and the plurality of second semiconductor regions, the fifth semiconductor region terminating closer to the second electrode than are bottoms of the plurality of gate trenches, the fifth semiconductor region having a dopant concentration higher than a dopant concentration of the first semiconductor region.

According to the disclosure described above, the carrier spreading resistance may be reduced.

(17) A method of manufacturing the silicon carbide semiconductor device according to one aspect of the present disclosure is a method of manufacturing the silicon carbide semiconductor device according to (1) or (9) described above and is as follows. A first process of forming the semiconductor substrate in which a first silicon carbide layer of the first conductivity type and a second silicon carbide layer of the second conductivity type are sequentially stacked, the first silicon carbide layer constituting the first semiconductor region and the second silicon carbide layer constituting the plurality of second semiconductor regions is performed. A second process of selectively forming the plurality of third semiconductor regions in the second silicon carbide layer, at a surface of the second silicon carbide layer is performed. A third process of selectively forming the plurality of fourth semiconductor regions in the second silicon carbide layer, at the surface region thereof is performed. A fourth process of forming the plurality of gate trenches that penetrate through the second silicon carbide layer in a depth direction, exposing the plurality of fourth semiconductor regions, the plurality of third semiconductor regions, and the plurality of second semiconductor regions along the sidewalls of the plurality of gate trenches and that reach the first silicon carbide layer, exposing the first semiconductor region along the bottoms of the plurality of gate trenches is performed. A fifth process of ion-implanting a dopant of the second conductivity type into the bottoms of the plurality of gate trenches from a direction orthogonal to the first main surface of the semiconductor substrate, thereby forming the plurality of first high concentration regions in portions of the first silicon carbide layer exposed along the bottoms of the plurality of gate trenches is performed. After the fifth process, a sixth process of forming the plurality of gate electrodes in the plurality of gate trenches via the plurality of gate insulating films is performed.

According to the disclosure described above, the plurality of first high concentration regions having the same width as the width of the gate trench may be formed in a self-aligned manner.

(18) A method of manufacturing the silicon carbide semiconductor device according to one aspect of the present disclosure is a method of manufacturing the silicon carbide semiconductor device according to (11) above and is as follows. A first process of forming the semiconductor substrate in which a first silicon carbide layer of the first conductivity type and a second silicon carbide layer of the second conductivity type are sequentially stacked, the first silicon carbide layer constituting the first semiconductor region and the second silicon carbide layer constituting the plurality of second semiconductor regions is performed. A second process of selectively forming the plurality of third semiconductor regions in the second silicon carbide layer, at a surface of the second silicon carbide layer is performed. A third process of selectively forming the plurality of fourth semiconductor regions in the second silicon carbide layer, at the surface region thereof is performed. A fourth process of forming the plurality of gate trenches that penetrate through the second silicon carbide layer in a depth direction, exposing the plurality of fourth semiconductor regions, the plurality of third semiconductor regions, and the plurality of second semiconductor regions along the sidewalls of the plurality of gate trenches and that reach the first silicon carbide layer, exposing the first semiconductor region along the bottoms of the plurality of gate trenches is performed. A fifth process of ion-implanting a dopant of the second conductivity type impurity into inner walls of the plurality of gate trenches from a direction oblique to the first main surface of the semiconductor substrate, thereby forming the plurality of first high concentration regions in portions of the first silicon carbide layer exposed along the inner walls of the plurality of gate trenches is performed. After the fifth process, a sixth process of forming the plurality of gate electrodes in the plurality of gate trenches via the plurality of gate insulating films, after the fifth process is performed.

According to the above disclosure, the plurality of first high concentration regions can be locally connected to the plurality of second semiconductor regions. The process of forming the plurality of second high concentration regions may be omitted, improving the throughput of the manufacturing process.

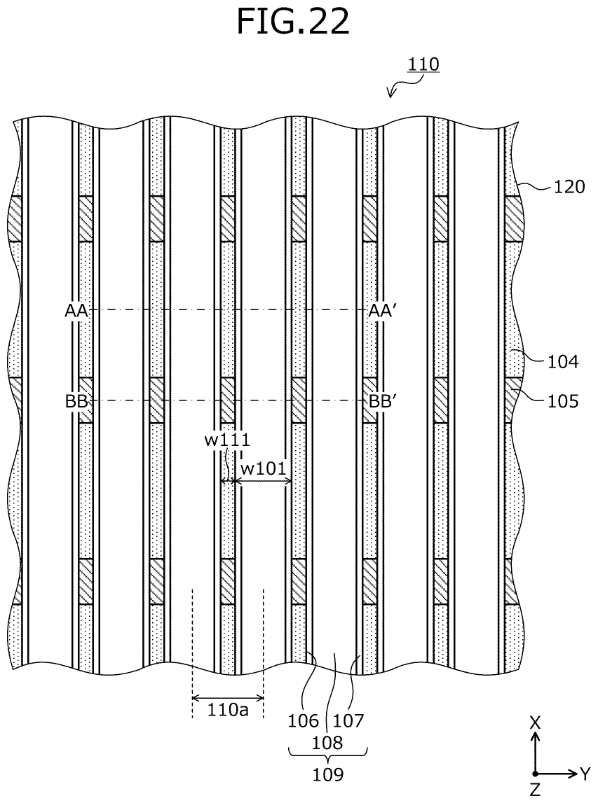

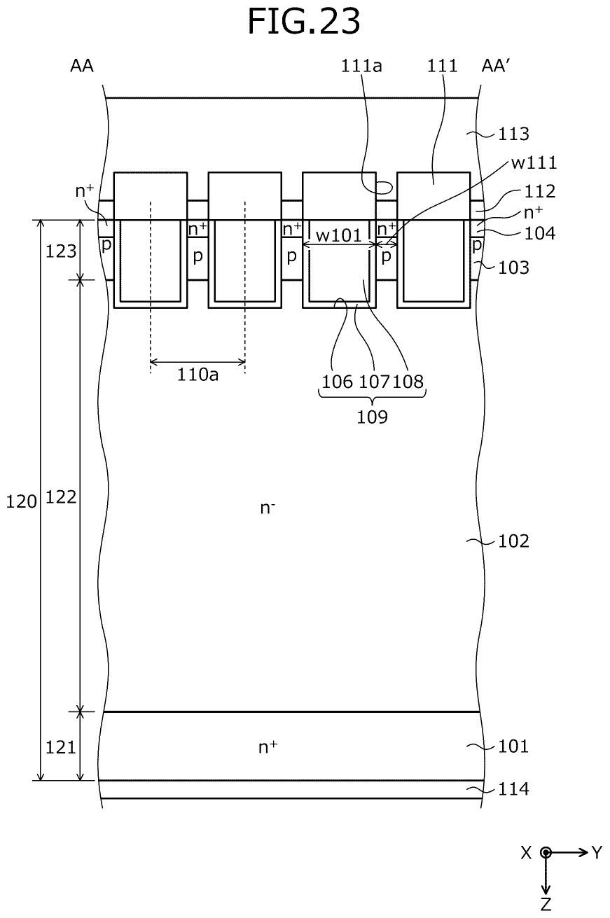

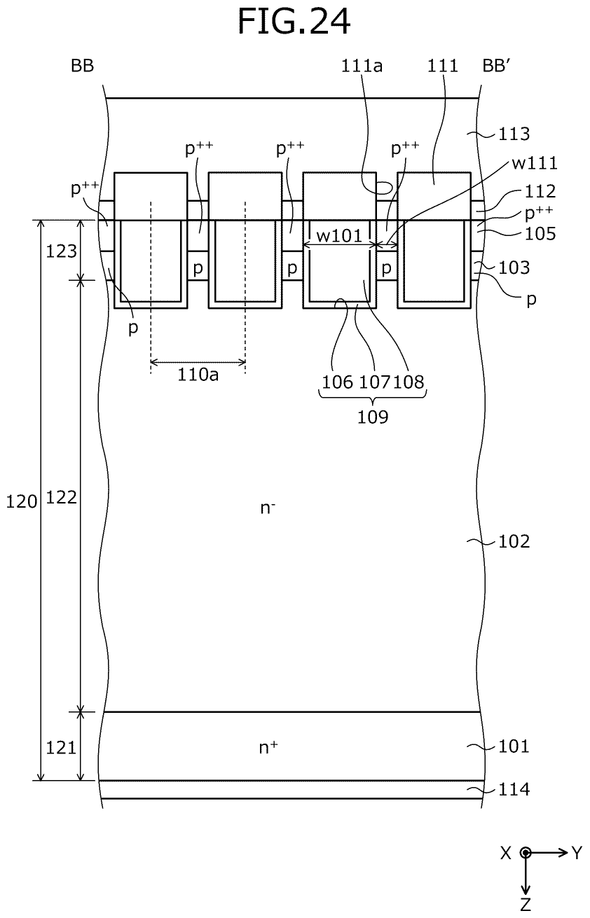

Findings underlying the present disclosure are discussed. First, a structure of a silicon carbide semiconductor device of a reference example is described. FIG. 22 is a plan view depicting a layout of the silicon carbide semiconductor device of the reference example as viewed from a front surface of a semiconductor substrate thereof. FIG. 22 depicts a layout (hatched portions) of n⁺-type source regions 104 and p⁺⁺-type contact regions 105. FIGS. 23 and 24 are cross-sectional views respectively depicting a structure along cutting lines AA-AA′ and BB-BB′ in FIG. 22. A silicon carbide semiconductor device 110 of the reference example depicted in FIGS. 22 to 24 is a vertical SiC-MOSFET with a trench gate structure having MOS gates 109 configuring a unit cell (functional unit of an element) 110a of a FinFET structure in a semiconductor substrate (semiconductor chip) 120, at a front surface (main surface on a p-type epitaxial layer 123) of the semiconductor substrate 120 containing SiC.

The semiconductor substrate 120 is formed by growing, on an n⁺-type starting substrate 121 containing SiC, epitaxial layers 122 and 123, in this order, the epitaxial layers 122 and 123 constituting an n-type drift region 102 and p-type base regions 103. The n⁺-type starting substrate 121 is an n⁺-type drain region 101. The trench gate structure is configured by the p-type base regions 103, n⁺-type source regions 104, p⁺⁺-type contact regions 105, and MOS gates 109. Each of the MOS gates 109 is configured by a gate trench 106, a gate insulating film 107, and a gate electrode 108. Each gate trench 106 has a predetermined width w101 and extends linearly in a first direction X parallel to the front surface of the semiconductor substrate 120, in a stripe-shape.

A region between centers of any adjacent two of the gate trenches 106 constitutes one unit cell 110a. A width (distance) (Fin width) w111 between the gate trenches 106 that are adjacent to one another is set narrow so that one channel (n-type inversion layer) is formed in nearly an entire area of each of the p-type base regions 103 between the gate trenches 106 that are adjacent to one another. This one channel formed between the gate trenches 106 that are adjacent to one another is in contact with different MOS gates 109 on both sides in a second direction Y, which is parallel to the front surface of the semiconductor substrate 120 and orthogonal to the first direction X. The gate trenches 106 penetrate through the p-type epitaxial layer 123 from the front surface of the semiconductor substrate 120 in a depth direction Z and terminate the n-type epitaxial layer 122 (n-type drift region 102).

The gate electrodes 108 are disposed in the gate trenches 106 via the gate insulating films 107. A portion of the p-type epitaxial layer 123 excluding the n⁺-type source regions 104 and the p⁺⁺-type contact regions 105 formed by ion implantation in the p-type epitaxial layer 123 constitutes the p-type base regions 103. The n⁺-type source regions 104 and the p⁺⁺-type contact regions 105 are selectively disposed between the front surface of the semiconductor substrate 120 and the p-type base regions 103 and are in contact with the p-type base regions 103. The n⁺-type source regions 104 and the p⁺⁺-type contact regions 105 are provided between the gate trenches 106 that are adjacent to one another, the n⁺-type source regions 104 and the p⁺⁺-type contact regions 105 being adjacent to one another and repeatedly alternating with one another in the first direction X.

The n-type drift region 102, the p-type base regions 103, the n⁺-type source regions 104, and the p⁺⁺-type contact regions 105 are in contact with the gate insulating films 107 at sidewalls of both gate trenches 106 disposed respectively on both sides in the second direction Y. The n-type drift region 102 borders the bottoms of the gate trenches 106 and is in contact with the gate insulating films 107 at the bottom of the gate trenches 106. An interlayer insulating film 111 is disposed over the entire front surface of the semiconductor substrate 120 and covers the gate electrodes 108. Contact electrodes 112 are disposed on the front surface of the semiconductor substrate 120 inside contact holes 111a of the interlayer insulating film 111 and are in ohmic contact with the n⁺-type source regions 104 and the p⁺⁺-type contact regions 105.

A front electrode 113 is disposed on the interlayer insulating film 111 and the contact electrodes 112 so as to be embedded in the contact holes 111a of the interlayer insulating film 111. The front electrode 113 is electrically connected to the n⁺-type source regions 104 and the p⁺⁺-type contact regions 105 via the contact electrodes 112. The front electrode 113 and the contact electrodes 112 function as a source electrode. A back electrode 114 is disposed on an entire back surface of the semiconductor substrate 120. The back electrode 114 is in contact with and electrically connected to the n⁺-type drain region 101 (n⁺-type starting substrate 121). The back electrode 114 functions as a drain electrode.

In the silicon carbide semiconductor device 110 of the reference example described above, in F. Udrea, et al. and Japanese Laid-Open Patent Publication No. 6631632, a Fin width w111 is narrow and thus, the electric field strength at the bottoms of the gate trenches 106 becomes large when the device is off. Therefore, the electric field concentrates in the gate insulating films 107 at the bottoms of the gate trenches 106, resulting in a problem of reduced breakdown voltage. Thus, a problem to be solved in the embodiments is, for example, improving the breakdown voltage in the silicon carbide semiconductor device with a trench gate structure in which unit cells of a FinFET structure are disposed.

Embodiments of a silicon carbide semiconductor device and a method of manufacturing a silicon carbide semiconductor device according to the present disclosure are described in detail with reference to the accompanying drawings. In the present description and accompanying drawings, layers and regions prefixed with n or p mean that majority carriers are electrons or holes. Additionally, + or − appended to n or p means that the dopant concentration is higher or lower, respectively, than layers and regions without + or −. In the description of the embodiments below and the accompanying drawings, main portions that are identical are given the same reference numerals and are not repeatedly described.

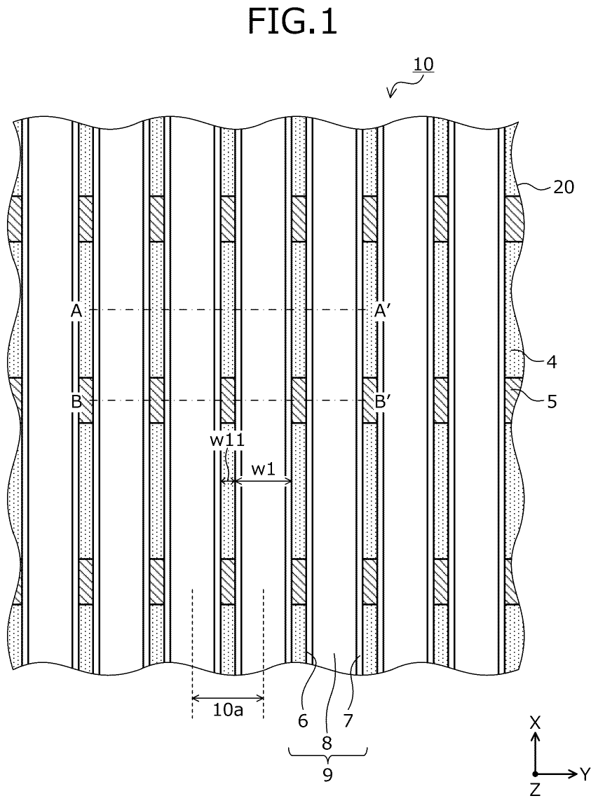

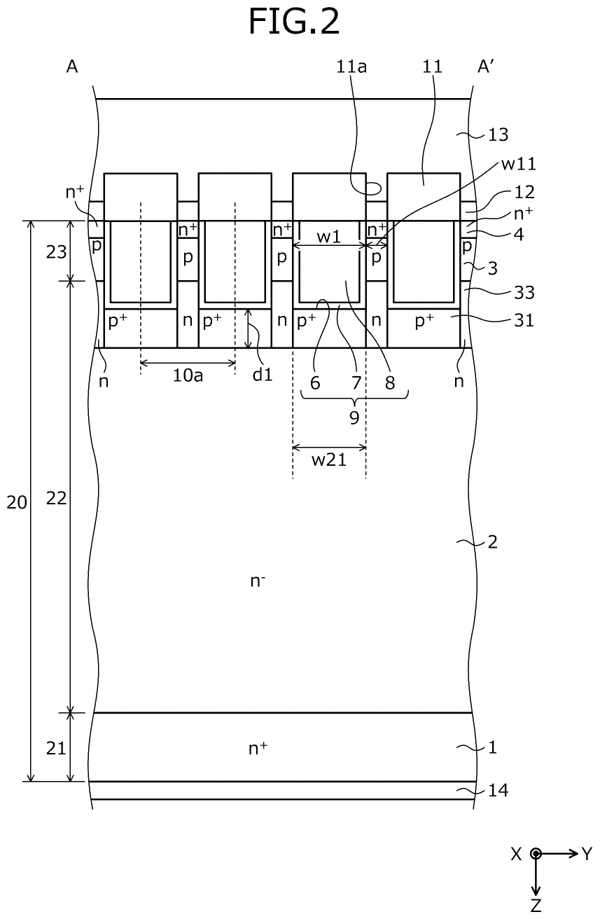

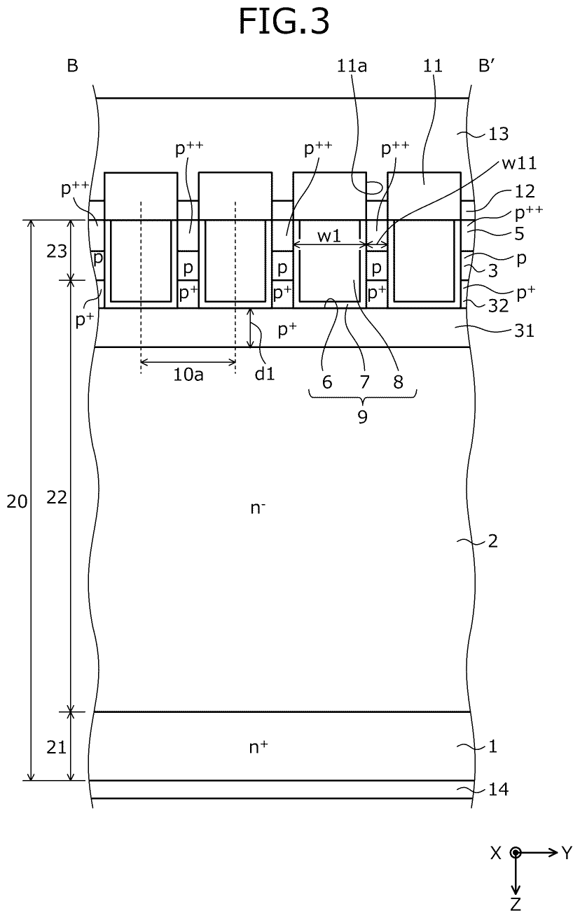

A silicon carbide semiconductor device according to a first embodiment for solving the problems mentioned above is described below. FIG. 1 is a plan view depicting a layout of the silicon carbide semiconductor device according to the first embodiment, as viewed from a front surface of a semiconductor substrate thereof. FIG. 1 depicts a layout of n⁺-type source regions 4 and p⁺⁺-type contact regions 5 (hatched portions). FIGS. 2 and 3 are cross-sectional views respectively depicting the structure along cutting lines A-A′ and B-B′ in FIG. 1. A silicon carbide semiconductor device 10 according to the first embodiment depicted in FIGS. 1 to 3 is a vertical SiC-MOSFET with a trench gate structure having MOS gates 9 configuring a unit cell (functional unit of a device) 10a of a FinFET structure in a semiconductor substrate (semiconductor chip) 20, at a front surface of the semiconductor substrate 20 containing silicon carbide (SIC).

The semiconductor substrate 20 is formed by growing, in this order, epitaxial layers (a first silicon carbide layer of a first conductive type and a second silicon carbide layer of a second conductivity type) 22 and 23 constituting, respectively, an n-type drift region (first semiconductor region) 2 and p-type base regions (second semiconductor regions) 3, on a front surface of an n⁺-type starting substrate 21 that contains SiC. The semiconductor substrate 20 has, as the front surface, a first main surface on the p-type epitaxial layer 23 and has, as a back surface, a second main surface (a back surface of the n⁺-type starting substrate 21) on the n⁺-type starting substrate 21. The n⁺-type starting substrate 21 constitutes an n⁺-type drain region 1. The trench gate structure is configured by the p-type base regions 3, the n⁺-type source regions (third semiconductor regions) 4, the p⁺⁺-type contact regions (fourth semiconductor regions) 5, and the MOS gates 9 (see FIGS. 2 and 3). The MOS gates 9 are configured by gate trenches 6, gate insulating films 7, and gate electrodes 8.

The FinFET structure is a so-called double gate structure in which a width (distance) (Fin width) w11 between any adjacent two of the gate trenches 6 is narrowed by a prescribed width and one channel (n-type inversion layer) formed in nearly an entire area of each of the p-type base regions 3 between the gate trenches 6 is sandwiched by the MOS gates 9 from both sides. The FinFET structure reduces the electric field in a direction parallel to the front surface of the semiconductor substrate 20, whereby carrier spreading is reduced, carrier mobility is improved, and the channel resistance is reduced, thereby reducing the on-resistance. The gate trenches 6 penetrate through the p-type epitaxial layer 23 from the front surface of the semiconductor substrate 20 in the depth direction Z and reach first p⁺-type regions 31 described later. A shape of each of the gate trenches 6, in a cross-sectional view, may be substantially rectangular or may be tapered (substantially trapezoidal) with the width progressively narrowing toward the bottom.

The gate trenches 6 extend linearly in the first direction X (longitudinal direction) parallel to the front surface of the semiconductor substrate 20 and are disposed in a stripe pattern. A region between the centers of any adjacent two of the gate trenches 6 constitutes one unit cell 10a. Multiple unit cells 10a each having the same structure are disposed adjacent to one another in the second direction Y (lateral direction of the gate trenches 6), which is parallel to the front surface of the semiconductor substrate 20 and orthogonal to the first direction X. A width w1 of each of the gate trenches 6 in the second direction Y is uniform over an entire area thereof in the first direction X. The Fin width w11 is uniform over an entire area thereof in the first direction X. The Fin width w11 is narrower than the width w1 of the gate trenches 6 in the second direction Y (w11<w1) and is not more than about 200 nm, e.g., about 100 nm.

The gate insulating films 7 are disposed in the gate trenches 6, along inner walls (sidewalls and bottom) of the gate trenches 6 and the gate electrodes 8 are disposed on the gate insulating films 7 so as to be embedded in the gate trenches 6. Portions of the p-type epitaxial layer 23 excluding the n⁺-type source regions 4 and the p⁺⁺-type contact regions 5 formed in the p-type epitaxial layer 23 by ion implantation constitute the p-type base regions 3. The n⁺-type source regions 4 and the p⁺⁺-type contact regions 5 are each selectively disposed between the front surface of the semiconductor substrate 20 and the p-type base regions 3, in contact with the p-type base regions 3. The n⁺-type source regions 4 and the p⁺⁺-type contact regions 5 are in ohmic contact with contact electrodes 12 (described later) on the front surface of the semiconductor substrate 20.

The n⁺-type source regions 4 and the p⁺⁺-type contact regions 5 are disposed between the gate trenches 6 adjacent to each other, are adjacent to one another, and repeatedly alternate with one another in the first direction X. The n⁺-type source regions 4 of the unit cells 10a adjacent to each other in the second direction Y face each other across the MOS gates 9 in the second direction Y. The p⁺⁺-type contact regions 5 of the unit cells 10a adjacent to each other in the second direction Y face each other across the MOS gates 9 in the second direction Y. The p⁺⁺-type contact regions 5 may terminate at substantially a same depth as the n⁺-type source regions 4, from the front surface of the semiconductor substrate 20 in the depth direction Z, or may reach a position closer to the n⁺-type drain region 1 (the back surface side of the semiconductor substrate 20) than are the n⁺-type source regions 4. Substantially the same depth means that the depths are the same within a range that includes an allowable error due to variations in the manufacturing process.

The n⁺-type source regions 4, the p⁺⁺-type contact regions 5, the p-type base regions 3, and n-type current spreading regions 33 described later are in contact with the gate insulating films 7 along the sidewalls of the gate trenches 6 located respectively on both sides of each said regions in the second direction Y. Between the n-type drift region 2 and the p-type base regions 3, the first and second p⁺-type regions (first and of second high concentration regions) 31 and 32 and the n-type current spreading region (fifth semiconductor region) 33 are selectively disposed at positions closer to the n⁺-type drain region 1 than are the bottoms of the gate trenches 6. A portion of the n-type epitaxial layer 22 excluding the first and second p⁺-type regions 31 and 32 and the n-type current spreading regions 33 formed in the n′-type epitaxial layer 22 by ion implantation constitutes the n-type drift region 2.

The first and second p⁺-type regions 31 and 32 have a function of depleting when the SiC-MOSFET turns off (or depleting the n-type current spreading regions 33, or both), thereby relaxing the electric field applied to the gate insulating films 7. The first p⁺-type regions 31 are disposed at positions facing the bottoms of the gate trenches 6, are apart from the p-type base regions 3, have a predetermined width w21, extend in the first direction X, and have substantially a same length as the longitudinal length of the gate trenches 6. The first p⁺-type regions 31 are in contact with the gate insulating films 7 at the bottoms of the gate trenches 6. The first p⁺-type regions 31 adjacent to each other extend directly below the p⁺⁺-type contact regions 5 between the gate trenches 6 adjacent to each other and are connected to each other. Substantially the same length means that the lengths are the same within a range that includes an allowable error due to variation in the manufacturing process.

The first p⁺-type regions 31 are not disposed directly below the n⁺-type source regions 4. That is, the first p⁺-type regions 31 are disposed at positions closer to the n⁺-type drain region 1 than are the bottoms of the gate trenches 6, face the bottoms of the gate trenches 6 and the p⁺⁺-type contact regions 5 in the depth direction Z, and are disposed in a ladder shape (lattice shape) as viewed from the front surface of the semiconductor substrate 20. The first p⁺-type regions 31 each have an upper surface (the surface facing the n⁺-type source regions 4) in contact with the second p⁺-type regions 32 and the gate insulating films 7 at the bottoms of the gate trenches 6. The first p⁺-type regions 31 each have a lower surface (the surface facing the n⁺-type drain region 1) in contact with the n-type drift region 2.

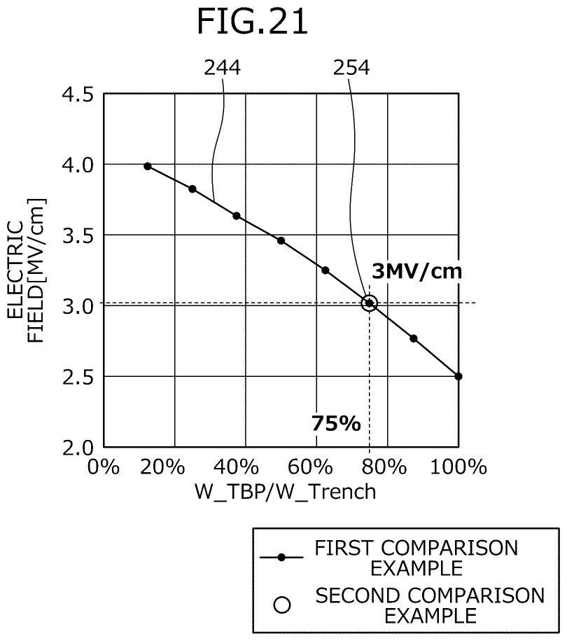

A width w21 in the second direction Y of the first p⁺-type regions 31 directly below the gate trenches 6 (n⁺-type drain region 1 side) is not more than the width w1 in the second direction Y of the gate trenches 6 and is wider than the Fin width w11 (w11<w21≤w1). The width w21 in the second direction Y of the first p⁺-type regions 31 directly below the gate trenches 6 is preferably, for example, 75% or more of the width w1 in the second direction Y of the gate trenches 6 (i.e., w1×0.75≤w21≤w1). This allows the electric field applied to the gate insulating films 7 at the bottoms of the gate trenches 6 to be 3 MV/cm or less (see FIG. 21).

By making the width w21 in the second direction Y of the first p⁺-type regions 31 directly below the gate trenches 6 not more than the width w1 in the second direction Y of the gate trenches 6, an increase in on-resistance due to Junction FET (JFET) resistance may be suppressed. The JFET resistance is the diffusion resistance of a JFET portion (i.e., the n-type current spreading regions 33) bordered by the first and second p⁺-type regions 31, 32 and the gate trenches 6. By making the width w21 in the second direction Y of the first p⁺-type regions 31 directly below the gate trenches 6 wider than the Fin width w11, the first p⁺-type regions 31 become a resistance component when a large current (short-circuit current) exceeding the rated current flows between the drain and source of the SiC-MOSFET during a load short circuit or arm short circuit thereby, improving the short-circuit tolerance.

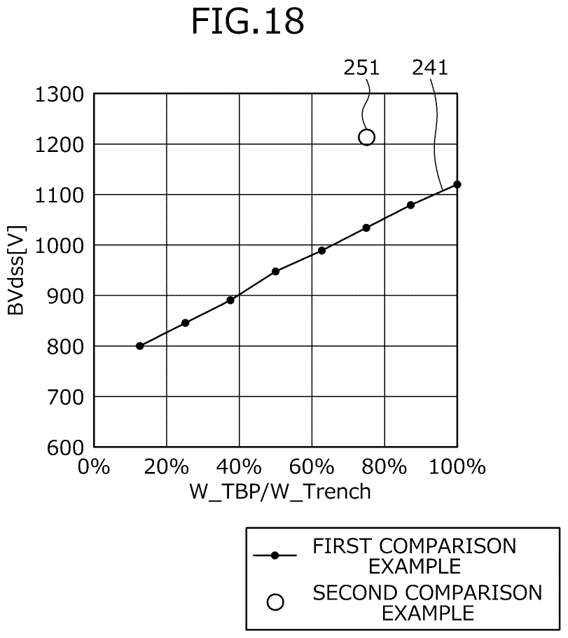

A depth d1 of each of the first p⁺-type regions 31 is preferably at least equal to the Fin width w11 (w11≤d1). The depth d1 of the first p⁺-type regions 31 is a distance in the depth direction Z from the bottoms of the gate trenches 6 (the upper surface of the first p⁺-type regions 31) to the lower surface of the first p⁺-type regions 31 and corresponds to a thickness of the first p⁺-type regions 31. The narrower is the width w21 in the second direction Y of the first p⁺-type regions 31 directly below the gate trenches 6, the lower is the breakdown voltage (breakdown voltage) BVdss. In order to obtain an effect of the FinFET structure and to secure a predetermined breakdown voltage BVdss to obtain the predetermined breakdown voltage, the depth d1 of the first p⁺-type regions 31 has to be increased (see FIG. 18). Specifically, the depth d1 of the first p⁺-type regions 31 is preferably, for example, 0.8 μm or more.

Between the gate trenches 6 adjacent to each other, the second p⁺-type regions 32 are disposed between the p-type base regions 3 and the first p⁺-type regions 31 and are in contact with the p-type base regions 3 and the first p⁺-type regions 31. The first p⁺-type regions 31 are electrically connected to the p-type base regions 3 by the second p⁺-type regions 32. Each of the second p⁺-type regions 32 is in contact with the gate insulating films 7 at the sidewalls of the gate trenches 6 respectively located on both sides of said second p⁺-type region 32 in the second direction Y. The second p⁺-type regions 32 are not disposed directly below the n⁺-type source regions 4. That is, the second p⁺-type regions 32 are disposed directly below the p⁺⁺-type contact regions 5 at positions closer to the n⁺-type source regions 4 than are the bottoms of the gate trenches 6 and are interspersed in the first direction X, between the gate trenches 6 adjacent to each other.

The n-type current spreading regions 33 constitute a so-called a current spreading layer (CSL) that reduces the spreading resistance of carriers. The n-type current spreading regions 33 are provided, whereby electron current may easily diffuse to the n-type drift region 2 from the channel formed in each of the p-type base regions 3 between the gate trenches 6 adjacent to each other when the SiC-MOSFET is on, thereby reducing the on-resistance. The n-type current spreading regions 33 each has an upper surface in contact with the p-type base regions 3 and a lower surface in contact with the n-type drift region 2. The n-type current spreading regions 33 each have side surfaces in the first direction X in contact with the first and second p⁺-type regions 31 and 32 and side surfaces in the second direction Y in contact with the first p⁺-type regions 31 and the gate insulating films 7 along the sidewalls of the gate trenches 6.

Between the gate trenches 6 adjacent to each other, the n-type current spreading regions 33 are disposed directly below the n⁺-type source regions 4 and are interspersed in the first direction X. The n-type current spreading regions 33 terminate at substantially the same depth toward the n⁺-type drain region 1 as the first p⁺-type regions 31. That is, the n-type current spreading regions 33 are arranged in a matrix shape and bordered by the first p⁺-type regions 31 at positions deeper toward the n-type drain region 1 than are the bottoms of the gate trenches 6. Between the gate trenches 6 adjacent to each other, the n-type current spreading regions 33 and the second p⁺-type regions 32 are disposed adjacent to each other and repeatedly alternate with one another in the first direction X.

The n-type current spreading regions 33 may be omitted. In this case, instead of the n-type current spreading regions 33, the n-type drift region 2 reaches the p-type base regions 3 to form the JFET portion. The interlayer insulating film 11 is disposed on the entire front surface of the semiconductor substrate 20 and covers the gate electrodes 8. The n⁺-type source regions 4 and the p⁺⁺-type contact regions 5 are exposed in contact holes 11a of the interlayer insulating film 11. The contact electrodes 12 are embedded in the contact holes 11a and are on the front surface of the semiconductor substrate 20. In a cross-sectional view, the contact holes 11a may have a substantially rectangular shape or may have a tapered shape that progressively narrows toward the front surface of the semiconductor substrate 20.

The contact electrodes 12 are in ohmic contact with the n⁺-type source regions 4 and the p⁺⁺-type contact regions 5. The front electrode 13 is disposed on the interlayer insulating film 11 and the contact electrodes 12 so as to be embedded in the contact holes 11a of the interlayer insulating film 11. The front electrode 13 is electrically connected to the n⁺-type source regions 4 and the p⁺⁺-type contact regions 5 via the contact electrodes 12. The front electrode 13 and the contact electrodes 12 function as a source electrode (first electrode). The back electrode 14 is disposed on the entire back surface of the semiconductor substrate 20. The back electrode 14 is in contact with and electrically connected to the n⁺-type drain region 1 (n⁺-type starting substrate 21). The back electrode 14 functions as a drain electrode (second electrode).

Operation of the silicon carbide semiconductor device 10 (SiC-MOSFET) according to the embodiments is described. When a voltage that is positive with respect to the source electrode (front electrode 13 and contact electrodes 12) is applied to the drain electrode (back electrode 14) (forward bias between the drain and source), pn junctions between the p⁺⁺-type contact regions 5, the p-type base regions 3, the first and second p⁺-type regions 31 and 32, the n-type current spreading regions 33, the n--type drift region 2, and the n⁺-type drain region 1 are reverse-biased. In this state, when voltage applied to the gate electrodes 8 is less than the gate threshold voltage, the SiC-MOSFET maintains the off state. At this time, the gate insulating films 7 at the bottoms of the gate trenches 6 are protected by the first p⁺-type regions 31, whereby the electric field applied to the gate insulating films 7 is relaxed. Thus, the breakdown voltage may be improved as compared to the reference structure (FIGS. 22 to 24) in which the bottoms of the gate trenches 106 are surrounded by the n⁻-type drift region 102.

Meanwhile, when gate voltage at least equal to the gate threshold voltage is applied to the gate electrodes 8 in a state where the drain-source is forward biased, one channel (n-type inversion layer) is formed in contact with different MOS gates 9 (gate insulating films 7 at the sidewalls of the gate trenches 6) on both sides of the channel in the second direction Y, over nearly an entire area, in the first direction X, of each of the p-type base regions 3 between the gate trenches 6 adjacent to each other. Thus, a drift current (main current) flows from the n⁺-type drain region 1 through the n-type drift region 2, the JFET portion (n-type current spreading regions 33), and the channel to the n⁺-type source regions 4, and the SiC-MOSFET turns on. When the SiC-MOSFET turns on, adverse effects of the electric field caused by the flow of the main current in the second direction Y are reduced by the FinFET structure, thereby reducing carrier spreading and improving carrier mobility. Thus, the channel resistance is lowered, reducing the on-resistance.

A method of manufacturing the silicon carbide semiconductor device 10 according to the first embodiment is described. First, the n-type epitaxial layer 22 constituting the n-type drift region 2 is grown by epitaxy (deposited) on the front surface of the n⁺-type starting substrate (n⁺-type starting wafer) 21, which constitutes the n⁺-type drain region 1. At this time, the n-type epitaxial layer 22 is grown by epitaxy to a thickness that is less than a predetermined thickness of the n-type epitaxial layer 22 for the completed product (silicon carbide semiconductor device 10).

In the active region, the first p⁺-type regions 31 are formed in a lattice shape as viewed from the surface of the n-type epitaxial layer 22 by ion implantation of a p-type dopant (dopant of the second conductivity type). Lower parts of the n-type current spreading regions 33 are formed by ion implantation of an n-type dopant in the active region in the entire surface region of the n-type epitaxial layer 22, at substantially the same depth as the first p⁺-type regions 31. The lower parts of the n-type current spreading regions 33 are arranged in a matrix shape and are bordered by the first p⁺-type regions 31.

The active region is a region through which the main current (drift current) flows when the SiC-MOSFET is on and in the active region, multiple unit cells 10a of the SiC-MOSFET are disposed adjacent to one another. The active region is surrounded by an edge termination region (not depicted). The edge termination region is a region that maintains the breakdown voltage by relaxing the electric field of the front side of the semiconductor substrate 20 and in the edge termination region, a predetermined breakdown voltage structure is disposed. The breakdown voltage is a limit voltage at which the semiconductor device does not malfunction or break down.

The n-type epitaxial layer 22 is further grown by epitaxy to increase the thickness thereof to be the predetermined thickness for the completed product. The second p⁺-type regions 32 are selectively formed by ion implantation of a p-type dopant in the part of the active region where the thickness of the n⁻-type epitaxial layer 22 has been increased. Upper parts of the n-type current spreading regions 33 are formed by the ion implantation of an n-type dopant in an entire area of the part of the active region where the thickness of the n⁻-type epitaxial layer 22 has been increased.

In between the gate trenches 6 adjacent to each other, the second p⁺-type regions 32 are formed at the positions facing the first p⁺-type regions 31 in the depth direction Z. For example, in between the gate trenches 6 adjacent to each other, the second p⁺-type regions 32 may face the first p⁺-type regions 31 in the depth direction Z and extend in a stripe shape in the second direction Y so as to be orthogonal to the formation region of the gate trenches 6. The upper parts of the n-type current spreading regions 33 are formed at positions facing the lower parts of the n-type current spreading regions 33 in the depth direction Z.

For example, when the second p⁺-type regions 32 extend in a stripe shape in the second direction Y, the upper parts of the n-type current spreading regions 33 are formed between the second p⁺-type regions 32 adjacent to each other, in a stripe shape extending in the second direction Y. Although the second p⁺-type regions 32 and the n-type current spreading regions 33 are also formed in the regions where the gate trenches 6 are to be formed, the portions formed in the regions where the gate trenches 6 are to be formed are removed when the gate trenches 6 are subsequently formed.

The second p⁺-type regions 32 and the upper part of the n-type current spreading regions 33 are formed penetrating the thickened part of the n⁻-type epitaxial layer 22 in the depth direction Z and are connected to the lower parts of the n-type current spreading regions 33, respectively, and the first p⁺-type regions 31 in the depth direction Z. A portion of the n-type epitaxial layer 22 closer to the n⁺-type starting substrate 21 than are the first and second p⁺-type regions 31 and 32 and the n-type current spreading regions 33 constitutes the n-type drift region 2.

The p-type epitaxial layer 23 constituting the p-type base regions 3 is grown by epitaxy on the n⁻-type epitaxial layer 22. The p-type epitaxial layer 23 is in contact with the upper parts of the n-type current spreading regions 33 and the second p⁺-type regions 32. By the processes up to this point, the semiconductor substrate (semiconductor wafer) 20 is fabricated (manufactured) in which the epitaxial layers 22 and 23 are deposited in the order stated, on the front surface of the n⁺-type starting substrate 21 (first process).

The n⁺-type source regions 4 and the p⁺⁺-type contact regions 5 are each selectively formed in surface regions of the p-type epitaxial layer 23 by ion implantation (second and third processes). Portions of the p-type epitaxial layer 23 closer to the n-type epitaxial layer 22 than are the n⁺-type source regions 4 and the p⁺⁺-type contact regions 5 constitute the p-type base regions 3. A p-type dopant concentration profile contributing to the gate threshold voltage may be adjusted by ion implantation in the p-type base regions 3.

A heat treatment is performed to activate all the ion-implanted dopants. The gate trenches 6 are formed which penetrate through the n⁺-type source regions 4, the p⁺⁺-type contact regions 5, and the p-type base regions 3, and reach the first p⁺-type regions 31 (fourth process). The n⁺-type source regions 4, the p⁺⁺-type contact regions 5, the p-type base regions 3, the second p⁺-type regions 32, and the n-type current spreading regions 33 are exposed along the sidewalls of the gate trenches 6, and the first p⁺-type regions 31 are exposed along the bottoms of the trenches 6.

By a general method, the gate electrodes 8 are embedded in the gate trenches 6 via the gate insulating films 7, thereby forming the MOS gates 9 (sixth process). The interlayer insulating film 11, the contact electrodes 12, the front electrode 13, and the back electrode 14 are formed by a general method. Thereafter, the semiconductor wafer (semiconductor substrate 20) is diced (cut) into individual chips, thereby completing the silicon carbide semiconductor device 10 depicted in FIGS. 1 to 3.

In the method of manufacturing the silicon carbide semiconductor device 10 according to the first embodiment described above, the first p⁺-type regions 31 directly below the gate trenches 6 may be formed by ion-implanting a p-type dopant into the bottoms of the gate trenches 6 from a direction orthogonal in the front surface of the semiconductor substrate 20, after the gate trenches 6 are formed but before the gate electrodes 8 are formed (fifth process). In this case, the first p⁺-type regions 31 having the width w21, which is substantially equal to the width w1 of the gate trenches 6 in the second direction Y, are formed in a self-aligned manner in surface regions of the n-type epitaxial layer 22 exposed at the bottoms of the gate trenches 6. Portions of the first p⁺-type regions 31 connecting the first p⁺-type regions 31 adjacent to each other are formed, for example, concurrently with the second p⁺-type regions 32.

As described above, according to the first embodiment, in the silicon carbide semiconductor device with the double gate structure in which one channel is formed in nearly an entire area of the p-type base region in the first direction between the gate trenches adjacent to each other, and the first p⁺-type regions fixed to the potential of the source electrode are disposed at positions facing the bottoms of the gate trenches. The first p⁺-type regions protect the gate insulating films at the bottoms of the gate trench and thereby reduce the electric field applied to the gate insulating films at the bottoms of the gate trenches, thereby improving the breakdown voltage.

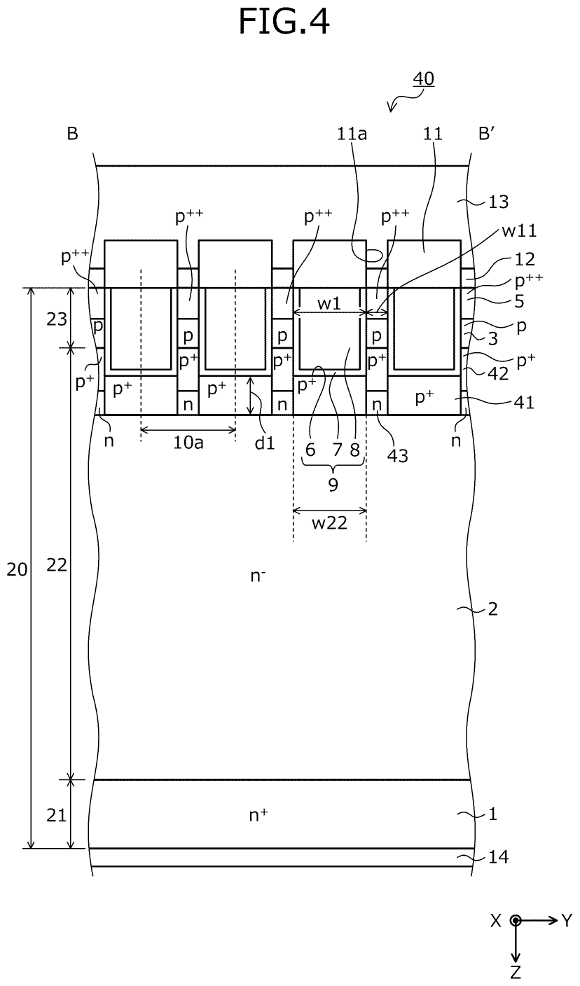

A silicon carbide semiconductor device according to a second embodiment solving the problems mentioned above is described. FIG. 4 is a cross-sectional view depicting a structure of the silicon carbide semiconductor device according to the second embodiment. A layout of the n⁺-type source regions 4, the p⁺⁺-type contact regions 5, and the MOS gates 9 of a silicon carbide semiconductor device 40 according to the second embodiment as viewed from the front surface of the semiconductor substrate 20 is the same as that of the first embodiment (see FIG. 1). FIG. 4 depicts the structure along cutting line B-B′ in FIG. 1. In the silicon carbide semiconductor device 40 according to the second embodiment, the structure along cutting line A-A′ in FIG. 1 is the same as that in FIG. 2 with an exception of the reference numerals 31, 33, and w21 being replaced with reference numerals 41, 43, and w22.

The silicon carbide semiconductor device 40 according to the second embodiment differs from the silicon carbide semiconductor device 10 according to the first embodiment (see FIG. 3) in the arrangement of the first and second p⁺-type regions 41 and 42, which are disposed in a vicinity of the bottoms of the gate trenches 6 to relax the electric field in portions directly below the p⁺⁺-type contact regions 5. In the second embodiment, the first p⁺-type regions 41 are disposed away from the p-type base regions 3, at positions facing the bottoms of the gate trenches 6; the first p⁺-type regions 41 have the predetermined width w22, extend in the first direction X, and have substantially the same length as the longitudinal length of the gate trenches 6. Each of the first p⁺-type regions 41 has an upper surface in contact with the gate insulating films 7 at the bottoms of the gate trenches 6 and a lower surface in contact with the n-type drift region 2.

The first p⁺-type regions 41 are not disposed between the gate trenches 6 adjacent to each other (i.e., directly below the p⁺⁺-type contact regions 5 and the n⁺-type source regions 4). In other words, the first p⁺-type regions 41 face only the bottoms of the gate trenches 6 at positions deeper toward the n⁺-type drain region 1 than are the bottoms of the gate trenches 6, and are arranged in the stripe shape as viewed from the front surface of the semiconductor substrate 20. The width w22 of the first p⁺-type regions 41 in the second direction Y is not more than the width w1 of the gate trenches 6 in the second direction Y, and is wider than the Fin width w11 (w11<w22≤w1), similar to the first embodiment.

Between the gate trenches 6 adjacent to each other, the second p⁺-type regions 42 are disposed between the n-type drift region 2 and the p-type base regions 3; each of the second p⁺-type regions 42 has an upper surface in contact with the p-type base regions 3. Similar to the first embodiment, the second p⁺-type regions 42 are disposed only directly below the p⁺⁺-type contact regions 5 and are not disposed directly below the n⁺-type source regions 4. In other words, similar to the first embodiment, the second p⁺-type regions 42 are interspersed in the first direction X between the gate trenches 6 adjacent to each other. The second p⁺-type regions 42 are in contact with the gate insulating films 7 along the sidewalls of both gate trenches 6 respectively arranged on both sides thereof in the second direction Y.

Each of the second p⁺-type regions 42 reaches a position closer to the n⁺-type drain region 1 than are the bottoms of the gate trenches 6 and has side surfaces in contact with the first p⁺-type regions 41 in the second direction Y. Between the second p⁺-type regions 42 and the n-type drift region 2 are n-type current spreading regions 43. Therefore, even when the first p⁺-type regions 41 is not arranged in the ladder shape as viewed from the front surface of the semiconductor substrate 20 similar to the first embodiment, the first p⁺-type regions 41 are electrically connected to the p-type base regions 3 by the second p⁺-type regions 42. The n-type current spreading regions 43 are directly below the second p⁺-type regions 42 and extend in the first direction X, having a length that is substantially equal to the longitudinal length of the gate trenches 6.

The n-type current spreading regions 43 extend in the first direction X and have a length substantially equal to the longitudinal length of the gate trenches 6, whereby the carrier spreading resistance is reduced in the first direction X. Each of the n-type current spreading regions 43 has an upper surface in contact with the p-type base regions 3 directly below the n⁺-type source regions 4 and in contact with the second p⁺-type regions 42 directly below the p⁺⁺-type contact regions 5. The n-type current spreading regions 43 border the side surfaces and the lower surfaces of the second p⁺-type regions 42 in the first direction X. Each of the n-type current spreading regions 43 has side surfaces in the second direction Y in contact with the gate insulating films 7 along the sidewalls of the gate trenches 6 and the first p⁺-type regions 41. Each of the n-type current spreading regions 43 has a lower surface in contact with the n⁻-type drift region 2.

A method of manufacturing the silicon carbide semiconductor device 40 according to the second embodiment differs from the method of manufacturing the silicon carbide semiconductor device 10 according to the first embodiment in the layout of the first p⁺-type regions 41 disposed in a vicinity of the bottoms of the gate trenches 6 to relax the electric field and the depth of the second p⁺-type regions 42 disposed in the vicinity of the bottoms of the gate trenches 6 to relax the electric field. Specifically, similar to the first embodiment, the n⁻-type epitaxial layer 22 is grown by epitaxy on the front surface of the n⁺-type starting substrate 21 to the thickness less than the predetermined thickness of the n⁻-type epitaxial layer 22 for the completed product (silicon carbide semiconductor device 40).

By ion implantation of a p-type dopant, the first p⁺-type regions 41 are each formed in a stripe shape in surface regions of the n⁻-type epitaxial layer 22 in the active region as viewed from the surface of the n⁻-type epitaxial layer 22. By ion implantation of an n-type dopant, the lower parts of the n-type current spreading regions 43 are formed in the entire surface region of the n-type epitaxial layer 22 in the active region at substantially the same depth as the depth of the first p⁺-type regions 41. The lower parts of the n-type current spreading regions 43 are disposed in the entire region between the first p⁺-type regions 41 adjacent to each other, the lower parts each being formed in a stripe shape extending in the first direction X.

Similar to the first embodiment, the thickness of the n-type epitaxial layer 22 is increased to the predetermined thickness for the completed product. The second p⁺-type regions 42 are formed in the part where the thickness of the n⁻-type epitaxial layer 22 has been increased, in the same layout as the second p⁺-type regions 32 in the first embodiment. At this time, the second p⁺-type regions 42 are terminated at positions deeper than are the bottoms of the gate trenches 6 formed in a later process. Therefore, the second p⁺-type regions 42 are terminated at positions deeper than are top surfaces of the first p⁺-type regions 41, respectively, connecting the first and second p⁺-type regions 41 and 42 in the second direction Y.

By terminating the second p⁺-type regions 42 at positions deeper than are the bottoms of the gate trenches 6 in this way, the first and second p⁺-type regions 41, 42 are maintained in a state of being respectively connected in the second direction Y even after the gate trenches 6 are formed in a later process. Thus, the upper and lower parts of the n-type current spreading regions 43 are connected to each other in the depth direction Z.

The first p⁺-type regions 41 may be formed by ion-implanting a p-type dopant into the bottoms of the gate trenches 6 from a direction orthogonal to the front surface of the semiconductor substrate 20 after the gate trenches 6 are formed but before the gate electrodes 8 are formed (fifth process). In this case, the first p⁺-type regions 41 having the width w22, which is substantially equal to the width w1 of the gate trenches 6 in the second direction Y, are formed in a self-aligned manner in surface regions of the n-type epitaxial layer 22 exposed at the bottoms of the gate trenches 6.

A portion of the n-type epitaxial layer 22 closer to the n⁺-type starting substrate 21 than are the first and second p⁺-type regions 41 and 42 and the n-type current spreading regions 43 constitutes the n′-type drift region 2. Thereafter, similar to the first embodiment, the processes following the epitaxial growth of the p-type epitaxial layer 23 are performed sequentially, thereby completing the silicon carbide semiconductor device 40 depicted in FIG. 4.

As described above, according to the second embodiment, the same effects as those of the first embodiment may be obtained. According to the second embodiment, the n-type current spreading region extends in the first direction to have a length substantially equal to the longitudinal length of the gate trenches, whereby the carrier spreading resistance in the first direction is reduced and thus, further enabling reduction of the on-resistance. According to the second embodiment, the first p⁺-type region and the second p⁺-type region do not face each other in the depth direction between the gate trenches adjacent to each other. Therefore, the alignment accuracy between the first p⁺-type region and the second p⁺-type region does not need to be considered, thereby simplifying the manufacturing process.

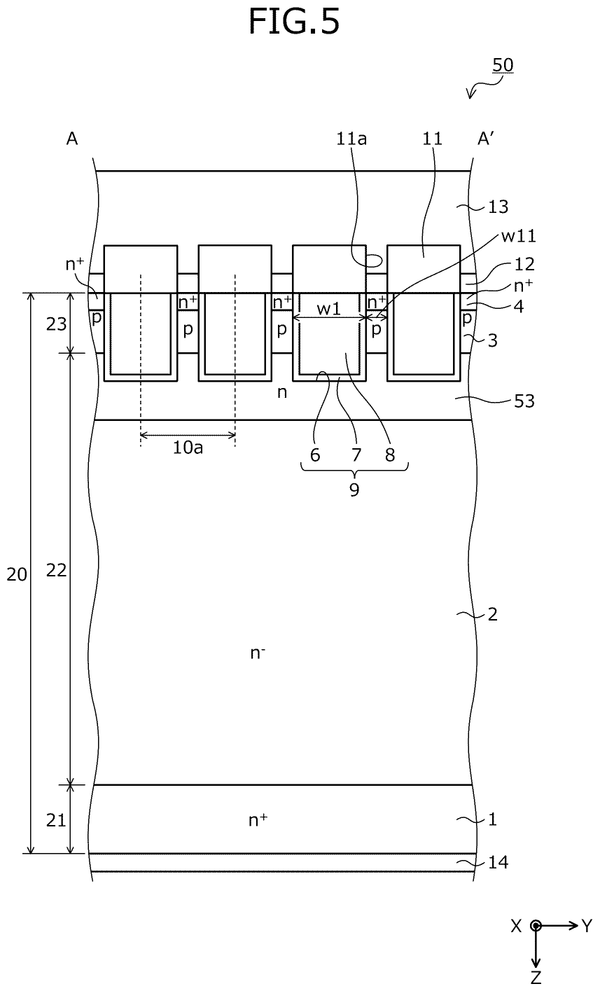

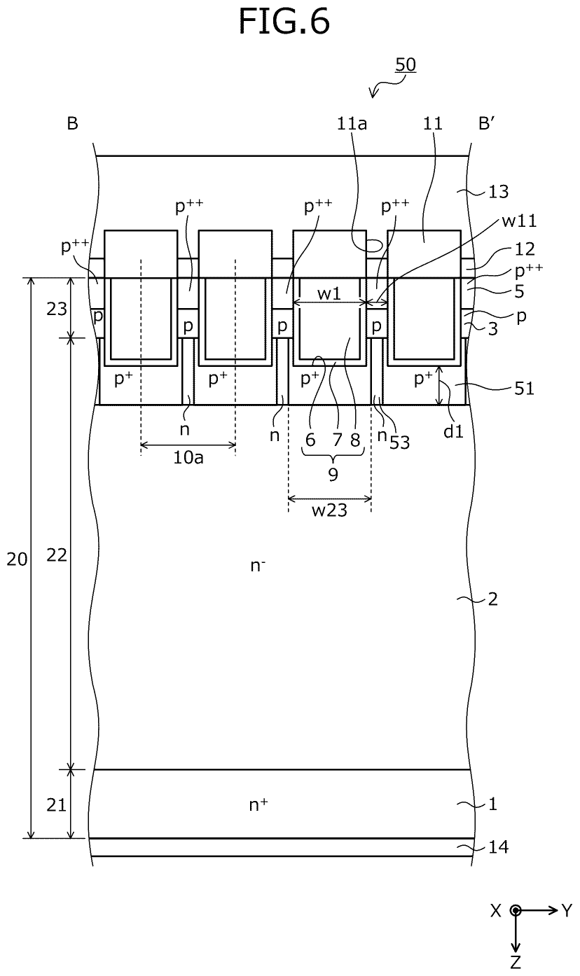

A silicon carbide semiconductor device according to a third embodiment for solving the above problems is described. FIGS. 5 and 6 are cross-sectional views depicting the structure of the silicon carbide semiconductor device according to the third embodiment. A layout of the n⁺-type source regions 4, the p⁺⁺-type contact regions 5, and the MOS gates 9 of a silicon carbide semiconductor device 50 according to the third embodiment, as viewed from the front surface of the semiconductor substrate 20, is the same as that of the first embodiment (see FIG. 1). FIGS. 5 and 6 respectively depict the structure along cutting lines A-A′ and B-B′ in FIG. 1.

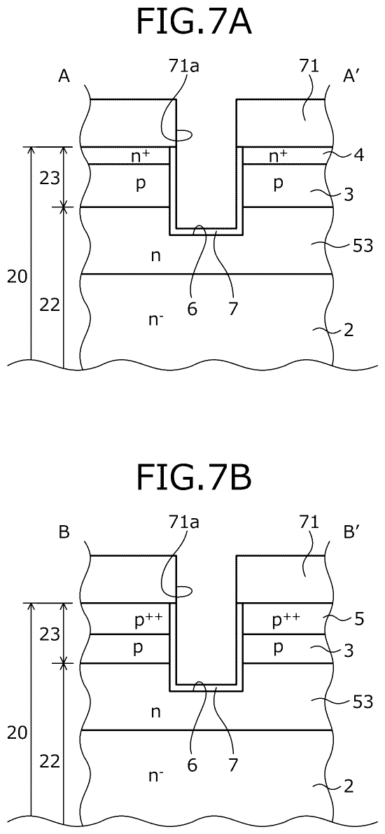

FIGS. 7A, 7B, 8A, 8B, 9A, 9B, 10A, and 10B are cross-sectional views depicting states during the manufacture of the silicon carbide semiconductor device according to the third embodiment. FIGS. 7A to 10A depict states of the structure depicted in FIG. 5 (cross-section where the n⁺-type source regions 4 are disposed) during manufacture and FIGS. 7B to 10B depict states of the structure depicted in FIG. 6 (cross-section where the p⁺⁺-type contact regions 5 are disposed) during manufacture. In FIGS. 7A to 10B, the structure in a vicinity of one of the gate trenches 6 is depicted at a different scale from that in FIGS. 5 and 6 so as to clarify the method of forming first p⁺-type regions 51.

The silicon carbide semiconductor device 50 according to the third embodiment differs from the silicon carbide semiconductor device 10 according to the first embodiment (see FIG. 3) in the following two points. A first difference is that the first p⁺-type regions 51 for relaxing the electric field in the vicinity of the bottoms of the gate trenches 6 are disposed only between the p⁺⁺-type contact regions 5 adjacent to each other in the second direction Y. The second difference is that the first p⁺-type regions 51 for relaxing the electric field in the vicinity of the bottoms of the gate trenches 6 are directly connected to the p-type base regions 3 directly below the p⁺⁺-type contact regions 5. In the third embodiment, the second p⁺-type regions for relaxing the electric field in the vicinity of the bottoms of the gate trenches 6 (corresponds to the reference numeral 32 in FIG. 3) are not disposed.

Specifically, the first p⁺-type regions 51 are disposed at positions facing the bottoms of the gate trenches 6 and in the second direction Y as viewed from the front surface of the semiconductor substrate 20, face only the p⁺⁺-type contact regions 5; the first p⁺-type regions 51 have substantially the same width as and are interspersed at substantially the same intervals as the p⁺⁺-type contact regions 5. The first p⁺-type regions 51 do not face the n⁺-type source regions 4 in the second direction Y. Substantially the same width and substantially the same interval mean that the widths are the same within a range that includes an allowable error due to variation in the manufacturing process and the intervals are the same within a range that includes an allowable error due to variation in the manufacturing process. Each of the first p⁺-type regions 51 has an upper surface in contact with the gate insulating films 7 along the bottoms of the gate trenches 6 and a lower surface in contact with the n-type drift region 2.

The width w23 of each of the first p⁺-type regions 51 in the second direction Y is wider than the width w1 of each of the gate trenches 6 in the second direction Y. The first p⁺-type regions 51 extend along a sidewall (one sidewall or both sidewalls) of the gate trenches 6 to the p-type base regions 3, are in contact with the gate insulating films 7 along the sidewall(s) of the gate trenches 6, and are directly connected to the p-type base regions 3. The first p⁺-type regions 51 may be disposed in an entire area between the n-type drift region 2 and the p-type base regions 3, directly below the p⁺⁺-type contact regions 5. The first p⁺-type regions 51 are not disposed directly below the n⁺-type source regions 4, similar to the first embodiment.

Between the n-type drift region 2 and the p-type base regions 3, a portion other than the first p⁺-type regions 51 constitutes an n-type current spreading region 53. Between the n-type drift region 2 and the p-type base regions 3, the first p⁺-type regions 51 and portions of the n-type current spreading region 53 alternately repeat with one another in the first direction X and border inner walls of the gate trenches 6. The n-type current spreading region 53 is in contact with the p-type base regions 3, the n-type drift region 2, and the first p⁺-type regions 51. That is, as viewed from the front surface side of the semiconductor substrate 20, the first p⁺-type regions 51 are arranged in a matrix shape, and the n-type current spreading region 53 are disposed in a lattice shape surrounding the peripheries of the first p⁺-type regions 51.

A method of manufacturing the silicon carbide semiconductor device 50 according to the third embodiment differs from the method of manufacturing the silicon carbide semiconductor device 10 according to the first embodiment in the following two points. The first difference is that the first p⁺-type regions 51 for relaxing the electric field in the vicinity of the bottoms of the gate trenches 6 are locally connected to the p-type base regions 3 by ion-implanting a p-type dopant into the n-type epitaxial layer 22 exposed at the sidewalls of the gate trenches 6, the p-type dopant being implanted from a direction oblique to the front surface of the semiconductor substrate 20 (hereinafter referred to as oblique ion implantation). The second difference is that the process for forming the second p⁺-type regions for relaxing the electric field in the vicinity of the bottoms of the gate trenches 6 (corresponding to the reference numeral 32 in FIG. 3) is omitted.

Specifically, first, similar to the first embodiment, as depicted in FIGS. 7A and 7B, the n-type current spreading region 53 is formed in the entire surface region of the n-type epitaxial layer 22 in the active region by performing the epitaxial growth of the n-type epitaxial layer 22 and forming the n-type current spreading region 53. Following that, similar to the first embodiment, the processes from the epitaxial growth of the p-type epitaxial layer 23 to the formation of the gate insulating films 7 are performed sequentially. The n⁺-type source regions 4, the p⁺⁺-type contact regions 5, the p-type base regions 3, and the n-type current spreading region 53 are exposed along the inner walls of the gate trenches 6, and these regions are covered by the gate insulating films 7 along the inner walls of the gate trenches 6.

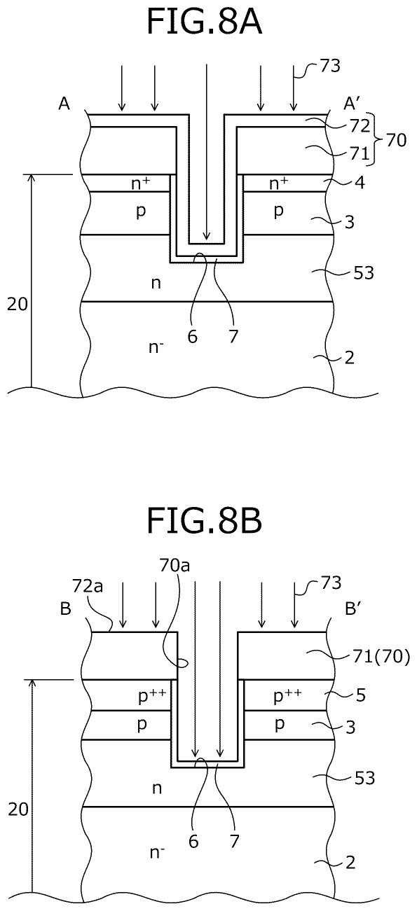

As depicted in FIGS. 8A and 8B, while leaving an oxide film mask 71, for example, used in forming the gate trenches 6, a resist mask 72 with openings corresponding to formation regions of the first p⁺-type regions 51 is formed on the front surface of the semiconductor substrate 20. The entire surface of each the gate insulating films 7 along the inner walls of the gate trenches 6 is exposed in an opening 71a of the oxide film mask 71. In openings 72a of the resist mask 72, the p⁺⁺-type contact regions 5 are exposed in a state covered by the oxide film mask 71, and the gate trenches 6 between the p⁺⁺-type contact regions 5 adjacent to each other in the second direction Y are exposed in a state covered by the gate insulating films 7.

The resist mask 72 covers the n⁺-type source regions 4 via the oxide film mask 71 and is formed along the inner walls of the gate trenches 6 between the n⁺-type source regions 4 adjacent to each other in the second direction Y; the resist mask 72 covers the gate insulating films 7. Thus, the gate insulating films 7 along the inner walls of the gate trenches 6 between the p⁺⁺-type contact regions 5 adjacent to each other in the second direction Y are exposed in openings 70a of a mask 70 that is constituted by the resist mask 72 and the oxide film mask 71. Portions exposed in the openings 70a of the mask 70 correspond to formation regions of the first p⁺-type regions 51.

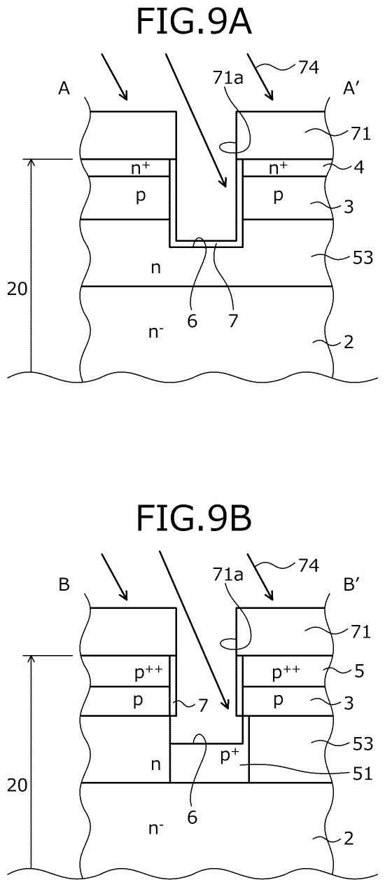

Using the resist mask 72 and the oxide film mask 71 as the mask 70, dry etching 73 such as reactive ion etching (RIE) is performed. This dry etching 73 removes portions of the gate insulating films 7 at the bottoms of the gate trenches 6 exposed in the openings 70a of the mask 70. In addition, by performing the dry etching 73 for a relatively long time, portions of the gate insulating films 7 at the sidewalls of the gate trenches 6, i.e., portions exposed in the openings 70a of the mask 70 and covering the n-type current spreading region 53, may be removed (see FIGS. 9A and 9B). Subsequently, the resist mask 72 is removed.

As depicted in FIGS. 9A and 9B, the oxide film mask 71 and the gate insulating films 7 are used as masks to perform oblique ion implantation 74 of a p-type dopant into the bottom and one sidewall of each of the gate trenches 6. Thus, the first p⁺-type regions 51 are each formed in a surface region of the inner wall of each of the gate trenches 6, from the bottom of the gate trench 6 to one sidewall of the gate trench 6, to a depth penetrating the n-type current spreading region 53 in the depth direction. The first p⁺-type regions 51 extend, directly below the p⁺⁺-type contact regions 5, from the bottom of each of the gate trenches 6 and along the one sidewall to the p-type base regions 3; each of the first p⁺-type regions 51 has an upper end in contact with the p-type base regions 3 (fifth process).

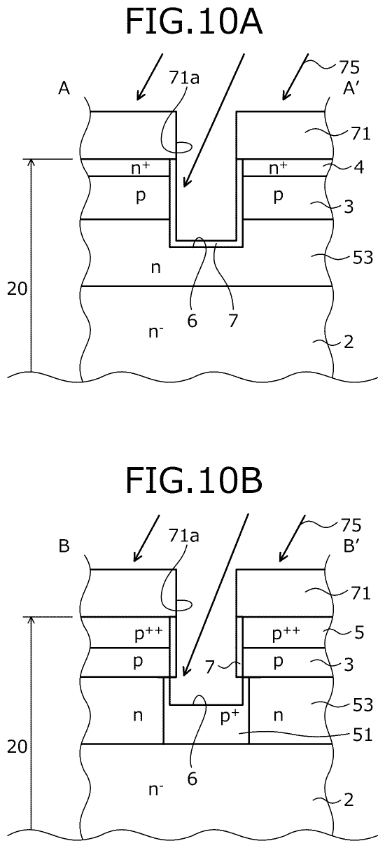

As depicted in FIGS. 10A and 10B, using the oxide film mask 71 and the gate insulating films 7 as masks, oblique ion implantation 75 of a p-type dopant is performed at the bottom and the other sidewall of each of the gate trenches 6.

Thus, the first p⁺-type regions 51 are each formed in the surface region of the inner wall of each of the gate trenches 6, from the bottom of the gate trench 6 to the other sidewall of the gate trench 6, to the depth penetrating the n-type current spreading region 53 in the depth direction. The first p⁺-type regions 51 extend, directly below the p⁺⁺-type contact regions 5, from the bottoms of the gate trenches 6 and along both sidewalls to the p-type base regions 3; the upper ends of the first p⁺-type regions 51 are in contact with the p-type base regions 3 (fifth process).

The first p⁺-type regions 51 and the p-type base regions 3 may be locally connected only at the one sidewall or the other sidewall of the gate trenches 6. In this case, either one of the oblique ion implantations 74 and 75 may be omitted. The first p⁺-type regions 51 adjacent to each other in the second direction Y may be connected to each other. A portion of the n-type epitaxial layer 22 closer to the n⁺-type starting substrate 21 than are the first p⁺-type regions 51 and the n-type current spreading region 53 constitutes the n-type drift region 2. Subsequently, the gate insulating films 7 are formed again to compensate for the missing portions of the gate insulating films 7 (i.e., the portions removed by the dry etching 73).

Thus, the entire inner wall of each of the gate trenches 6 is covered by the gate insulating films 7. The thickness of the gate insulating films 7 may be thicker in the portions thereof in contact with the first p⁺-type regions 51 than in the portions thereof in contact with the n-type current spreading region 53. All the gate insulating films 7 remaining on the sidewalls of the gate trenches 6 may be removed and thereafter, the gate insulating films 7 may be formed again to form the gate insulating films 7 to have a substantially uniform thickness in both the portion in contact with the first p⁺-type regions 51 and the portion in contact with the n-type current spreading region 53. Thereafter, the oxide film mask 71 is removed, and the subsequent processes following the formation of the gate electrodes 8 are performed sequentially, similar to the first embodiment, thereby completing the silicon carbide semiconductor device 50 depicted in FIGS. 5 and 6.

As described above, according to the third embodiment, the same effects as those of the first and second embodiments may be obtained. According to the third embodiment, the process of forming the second p⁺-type region for relaxing the electric field in the vicinity of the bottom of the gate trench may be omitted, thereby enabling a reduction in the number of processes.

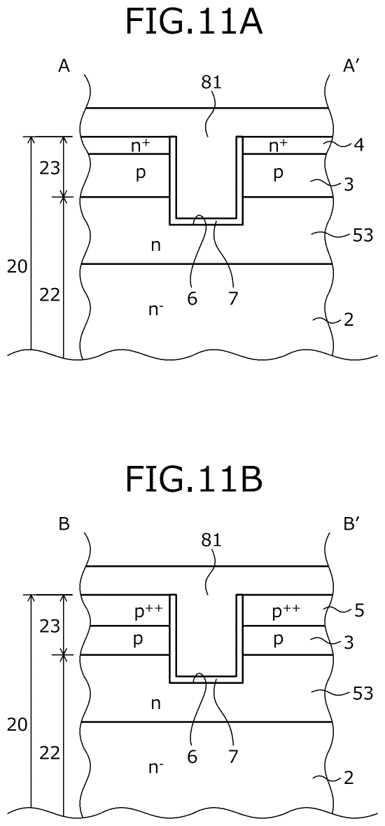

As a method of manufacturing a silicon carbide semiconductor device according to a fourth embodiment for solving the problems mentioned above, another example of the method of manufacturing the silicon carbide semiconductor device 50 according to the third embodiment is described below. FIGS. 11A, 11B, 12A, 12B, 13A, 13B, 14A, and 14B are cross-sectional views depicting states during manufacturing of the silicon carbide semiconductor device according to the fourth embodiment. In FIGS. 11A to 14B, the structure in a vicinity of one of the gate trenches 6 is depicted at a different scale from that in FIGS. 5 and 6 so as to clarify the method of forming first p⁺-type regions 51.

A method of manufacturing the silicon carbide semiconductor device according to the fourth embodiment differs from the method of manufacturing the silicon carbide semiconductor device according to the third embodiment (see FIGS. 7A to 10B) in that the first p⁺-type regions 51 are formed using a polysilicon (poly-Si) layer 81 as a mask instead of the resist mask 72 (see FIGS. 8A and 8B). Specifically, as depicted in FIGS. 11A and 11B, similar to the third embodiment, the processes from the epitaxial growth of the n-type epitaxial layer 22 to the formation of the gate insulating films 7 are performed sequentially. Thereafter, the oxide film mask 71 (see FIGS. 7A and 7B) used to form the gate trenches 6 is removed and the polysilicon layer 81 is deposited on the front surface of the semiconductor substrate 20 so as to be embedded in and completely fill the gate trenches 6.

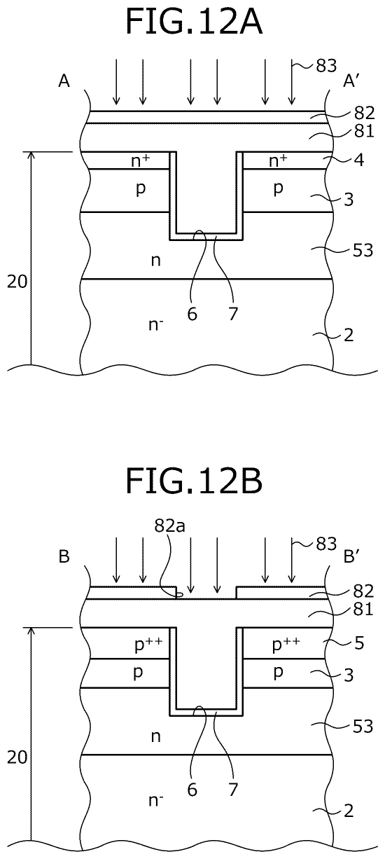

Thereafter, as depicted in FIGS. 12A and 12B, a resist mask 82 is formed on the polysilicon layer 81, with only portions corresponding to the formation region of the first p⁺-type regions 51 being opened. By depositing the polysilicon layer 81 on the front surface of the semiconductor substrate 20 so that the gate trenches 6 are completely filled, the surface of the polysilicon layer 81 is a flat surface and substantially parallel to the front surface of the semiconductor substrate 20. Therefore, the resist mask 82 may be formed on the polysilicon layer 81 with a uniform thickness and flatness. In openings 82a of the resist mask 82, the gate trenches 6 between the p⁺⁺-type contact regions 5 adjacent to each other in the second direction Y are exposed in a state of being covered by the polysilicon layer 81 and the gate insulating films 7.

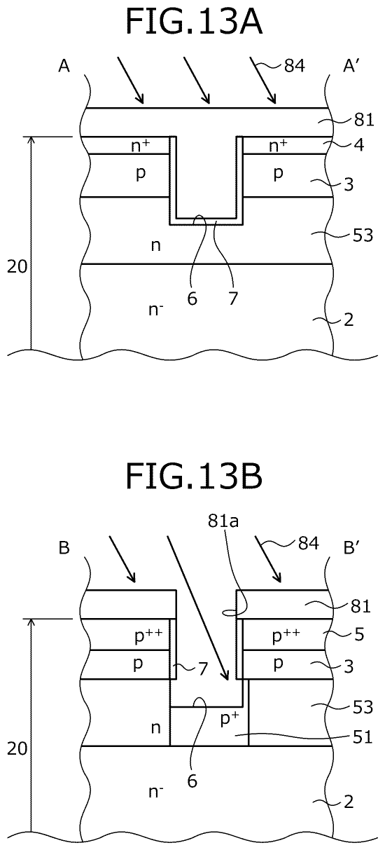

Thereafter, dry etching 83 such as RIE is performed using the resist mask 82. This dry etching 83 removes portions of the polysilicon layer 81 and the gate insulating films 7 along the bottom of each of the gate trenches 6, i.e., the portions exposed in the openings 82a of the resist mask 82. In addition, by performing the dry etching 83 for a relatively long time, portions of the gate insulating films 7 along the sidewalls of the gate trenches 6, i.e., the portions exposed in the openings 82a of the resist mask 82 and covering the n-type current spreading region 53, may be removed. Thus, openings 81a are formed in the polysilicon layer 81, exposing portions corresponding to the formation regions of the first p⁺-type regions 51 (see FIGS. 13A and 13B). The resist mask 82 is then removed.

As depicted in FIGS. 13A and 13B, oblique ion implantation 84 of a p-type dopant in the bottom and one sidewall of each of the gate trenches 6 is performed using the polysilicon layer 81 and the gate insulating films 7 as masks. Thus, the first p⁺-type regions 51 are each formed in a surface region of the inner wall of each of the gate trenches 6, from the bottom of the gate trench 6 to one sidewall of the gate trench 6, to a depth penetrating the n-type current spreading region 53 in the depth direction. The first p⁺-type regions 51 extend, directly below the p⁺⁺-type contact regions 5, from the bottom of each of the gate trenches 6 and along one sidewall to the p-type base regions 3, upper ends of the first p⁺-type regions 51 being in contact with the p-type base regions 3 (fifth process).

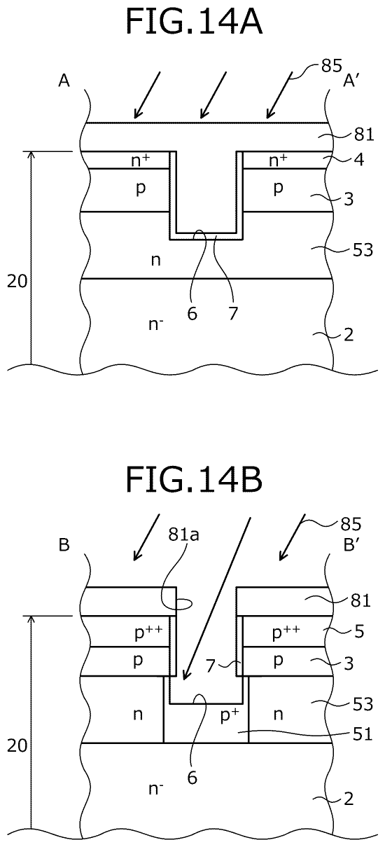

Thereafter, as depicted in FIGS. 14A and 14B, oblique ion implantation 85 of a p-type dopant in the bottom and the other sidewall of each of the gate trenches 6 is performed using the polysilicon layer 81 and the gate insulating films 7 as masks. Thus, the first p⁺-type regions 51 are each formed in a surface region of the inner wall of each of the gate trenches 6, from the bottom of the gate trench 6 to the other sidewall of the gate trench 6, to a depth penetrating the n-type current spreading region 53 in the depth direction Z. The first p⁺-type regions 51 extend, directly below the p⁺⁺-type contact regions 5, from the bottoms of the gate trenches 6 and along both sidewalls to the p-type base regions 3, the upper ends of the first p⁺-type regions 51 being in contact with the p-type base regions 3 (fifth process).

Similar to the third embodiment, either one of the oblique ion implantations 84 and 85 may be omitted, or the first p⁺-type regions 51 adjacent to each other in the second direction Y may be connected to each other. Subsequently, the gate insulating films 7 are formed again, similar to the third embodiment. Thereafter, the polysilicon layer 81 is deposited again to be embedded in and completely fill the gate trenches 6. Next, the polysilicon layer 81 is etched back, leaving only portions of the polysilicon layer 81 constituting the gate electrodes 8 inside the gate trenches 6. Thereafter, similar to the third embodiment, the subsequent processes following the formation of the interlayer insulating film 11 are performed sequentially, thereby completing the silicon carbide semiconductor device 50 depicted in FIGS. 5 and 6.

As described above, according to the fourth embodiment, the same effects as those of the first to third embodiments may be obtained. According to the fourth embodiment, the polysilicon layer that constitutes the gate electrodes 8 may be used as a mask to form the first p⁺-type regions for relaxing the electric field at the bottoms of the gate trenches.

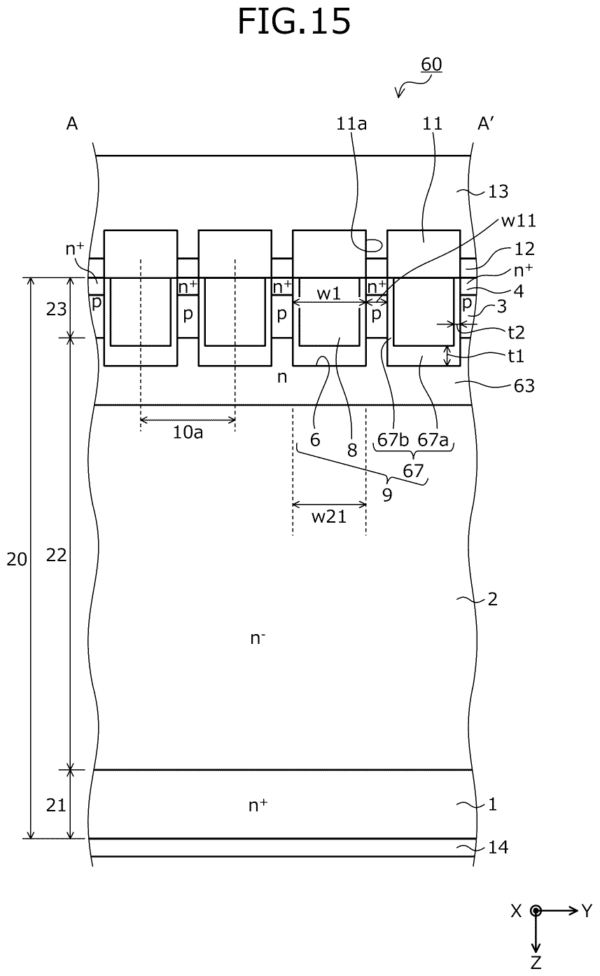

A silicon carbide semiconductor device according to a fifth embodiment for solving the problems mentioned above is described below. FIG. 15 is a cross-sectional view depicting a structure of the silicon carbide semiconductor device according to the fifth embodiment. A layout of the n⁺-type source regions 4, the p⁺⁺-type contact regions 5, and the MOS gates 9 of a silicon carbide semiconductor device 60 according to the fifth embodiment, as viewed from the front surface of the semiconductor substrate 20, is obtained by replacing reference numeral 7 in FIG. 1 with reference numeral 67 (67b). FIG. 15 depicts the structure along cutting line A-A′ in FIG. 1. In the silicon carbide semiconductor device 60 according to the fifth embodiment, the structure along cutting line B-B′ in FIG. 1 is obtained by replacing the n⁺-type source regions 4 in FIG. 15 with the p⁺⁺-type contact regions 5 (see FIG. 3).

The silicon carbide semiconductor device 60 according to the fifth embodiment differs from the silicon carbide semiconductor device 10 according to the first embodiment (see FIGS. 2 and 3) in the following two points. A first difference is that, gate insulating films 67 are disposed along the inner wall (bottom and sidewalls) of each of the gate trenches 6; each of the gate insulating films 67 has a portion 67a along the bottom of the gate trenches 6 (hereinafter referred to as a gate insulating film along the bottoms of the gate trenches 6) with a thickness t1 that is thicker than a thickness t2 of portions 67b thereof along the sidewalls of the gate trenches 6 (hereinafter referred to as gate insulating films along the sidewalls of the gate trenches 6). The second difference is that the first and second p⁺-type regions (corresponding to the reference numerals 31 and 32 in FIG. 3) for relaxing the electric field in the vicinity of the bottoms of the gate trenches 6 are not disposed, and an entire area between the p-type base regions 3 and the n-type drift region 2 is constituted by an n-type current spreading region 63.

In the fifth embodiment, the thickness t1 of the gate insulating films 67a along the bottom of each of the gate trenches 6 is thicker than the Fin width w11 (t1>w11). By increasing the thickness t1 of the gate insulating films 67a along the bottom of each of the gate trenches 6, the breakdown voltage of the gate insulating films 67 becomes higher (the electric field strength at the bottoms of the gate trenches 6 decreases). Thus, the gate insulating films 67a along the bottom of each of the gate trenches 6 may be protected without providing the first and second p⁺-type regions for relaxing the electric field in the vicinity of the bottoms of the gate trenches 6. By not providing the first and second p⁺-regions for relaxing the electric field in the vicinity of the bottoms of the gate trenches 6, the electron current easily spreads from the channel to the n-type drift region 2 when the SiC-MOSFET turns on, and the carrier spreading resistance is reduced, thereby enabling reduction of the on-resistance.

The thickness t2 of the gate insulating films 67b along the sidewalls of the gate trenches 6 is the same as that of the gate insulating films 7 of the first embodiment (see FIGS. 2 and 3). The n-type current spreading region 63 is disposed over the entire area between the p-type base regions 3 and the n-type drift region 2 and at the upper surface thereof, is in contact with the p-type base regions 3 while at the lower surface thereof, is in contact with the n-type drift region 2. The n-type current spreading region 63 extends in the first direction X, between the gate trenches 6 adjacent to each other, and has a length substantially equal to the longitudinal length of the gate trenches 6. The n-type current spreading region 63 has side surfaces in the second direction Y in contact with the gate insulating films 67b along the sidewalls of the gate trenches 6. The n-type current spreading region 63 borders the bottom of the gate trenches 6 and is in contact with the gate insulating films 67a along the bottom of each of the gate trenches 6.

A manufacturing method of the silicon carbide semiconductor device 60 according to the fifth embodiment differs from the manufacturing method of the silicon carbide semiconductor device 10 according to the first embodiment in the following two points. The first difference is that each of the gate insulating films 67 (67a, 67b) is formed so that the thickness t1 of a portion thereof at the bottom of each of the gate trenches 6 is thicker than the thickness t2 of a portion at the sidewalls. The second difference is that the process of forming the first and second p⁺-type regions for relaxing the electric field in the vicinity of the bottoms of the gate trenches 6 is not performed, and the n-type current spreading region 63 is formed over the entire surface region of the n-type epitaxial layer 22 in the active region.

As described above, according to the fifth embodiment, by increasing the thickness of the gate insulating films along the bottom of each of the gate trenches to the predetermined thickness, effects similar to those of the first to fourth embodiments may be obtained without providing the first and second p⁺-type regions for relaxing the electric field in the vicinity of the bottoms of the gate trenches. According to the fifth embodiment, the process of forming the first and second p⁺-type regions for relaxing the electric field in the vicinity of the bottoms of the gate trenches may be omitted, thereby enabling a reduction in the number of processes.

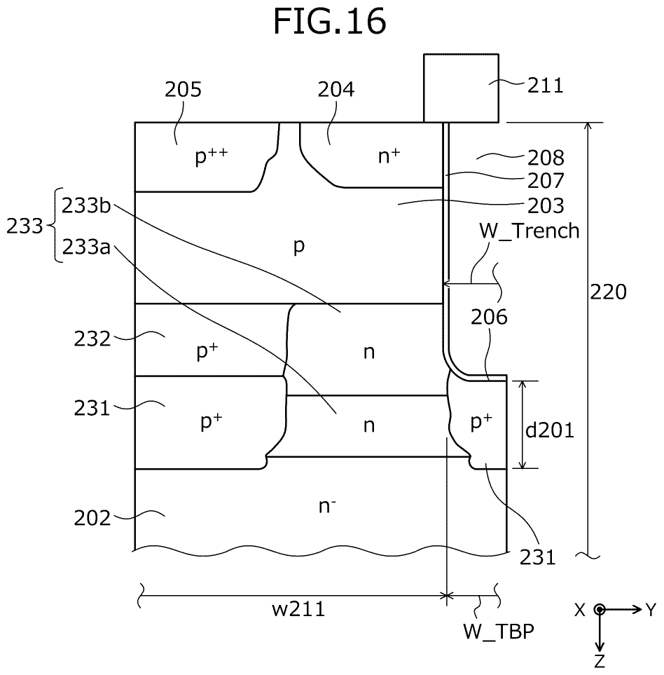

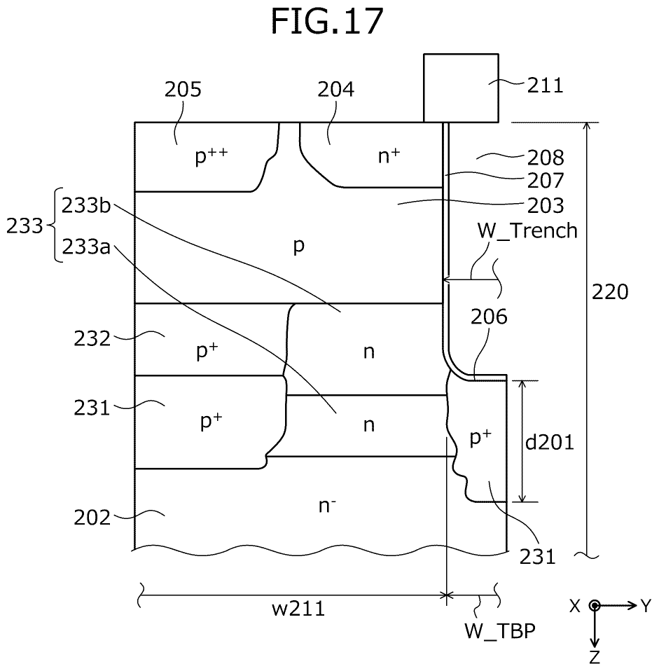

A relationship between the width w21 in the second direction Y of a part of each of a first p⁺-type regions 31 directly below the gate trenches 6 and the width w1 in the second direction Y of each of the gate trenches 6 was verified for the silicon carbide semiconductor device 10 (see FIG. 2) according to the first embodiment. Electrical characteristics obtained by the part of the first p⁺-type regions 31 directly below the gate trenches 6 of the silicon carbide semiconductor device 10 according to the first embodiment are the same as the electrical characteristics obtained by the p⁺-type regions directly below the gate trenches of a normal SiC-MOSFET that does not have a FinFET structure. Therefore, normal SiC-MOSFETs (hereinafter, referred to as first and second comparison examples) were used for the verification. FIGS. 16 and 17 are cross-sectional views respectively depicting a structure in a vicinity of the gate trenches of the first and second comparison examples.

FIGS. 18, 19, 20, and 21 are characteristic diagrams depicting results of simulation of the relationship between TBP width W_TBP and trench width W_Trench of the first and second comparison examples. The trench width W_Trench is a width of each of multiple gate trenches 206 in the second direction Y (lateral direction). The TBP width W_TBP is a width of each of multiple first p⁺-type regions 231 directly below the gate trenches 206, respectively, in the second direction Y. The horizontal axis in FIGS. 18 to 21 is the ratio of the TBP width W_TBP to the trench width W_Trench (=W_TBP/W_Trench). The vertical axes in FIGS. 18 to 21 are respectively breakdown voltage BVdss [V], gate threshold voltage Vth [V], on-resistance RonA [mΩ·cm²], and electric field strength [MV/cm].

FIGS. 16 and 17 depict the first and second comparison examples in which a width w211 between any two of the gate trenches 206 adjacent to each other is relatively wide, the first and second comparison examples each having normal unit cells that are not the FinFET structure. FIGS. 16 and 17 respectively depict a half structure (a portion from a center of any one of the gate trenches 206 in the second direction Y to a center between said gate trench 206 and one of the gate trenches 206 adjacent thereto) of the unit cell (the portion between the centers of any two of the gate trenches 206 adjacent to each other) of the first and second comparison examples. The first and second comparison examples differ from the silicon carbide semiconductor device 10 according to the first embodiment in a layout of first and second p⁺-type regions 231 and 232 as viewed from the front surface of a semiconductor substrate 220 and differ in that the width w211 between the gate trenches 206 adjacent to each other is relatively wide. Specifically, the semiconductor substrate 220 is formed, by growing epitaxial layers constituting an n-type drift region 202 and a p-type base region 203 in this order on the n⁺-type starting substrate (not depicted) constituting the n⁺-type drain region.

A trench gate structure configured by the p-type base region 203, n⁺-type source regions 204, p⁺⁺-type contact regions 205, the gate trenches 206, gate insulating films 207, and gate electrodes 208 is disposed in the semiconductor substrate 220, at the front surface thereof (main surface having a p-type epitaxial layer constituting the p-type base region 203). The n⁺-type source regions 204 and the p⁺⁺-type contact regions 205 are diffused regions formed by ion implantation in surface regions of the semiconductor substrate 220, at the front surface thereof (surface regions of the p-type epitaxial layer constituting the p-type base region 203). The n⁺-type source regions 204 and the p⁺⁺-type contact regions 205 are selectively disposed between the front surface of the semiconductor substrate 220 and the p-type base region 203 and are in contact with the p-type base region 203.

The n⁺-type source regions 204 and the p⁺⁺-type contact regions 205 are in ohmic contact with a source electrode (not depicted) on the front surface of the semiconductor substrate 220. The p-type base region 203 and the n⁺-type source regions 204 extend, along sidewalls of the gate trenches 206, in the first direction X and have a length substantially equal to a longitudinal length of the gate trenches 206. The p-type base region 203 and the n⁺-type source regions 204 are in contact with the gate insulating films 207 along the sidewalls of the gate trenches 206. At the sidewalls of each gate trenches 206, a different one of the n⁺-type source regions 204 is in contact with the gate insulating film 207 of said each of the gate trenches 206. The p⁺⁺-type contact regions 205 are disposed in substantially a center between the gate trenches 206 adjacent to each other and are apart from the gate trenches 206.

Each of the gate trenches 206 extends in a stripe shape in the first direction X, similar to the first embodiment. The gate trenches 206 penetrate, in the depth direction Z, the n⁺-type source regions 204 and the p-type base region 203 from the front surface of the semiconductor substrate 220 and reach the first p⁺-type regions 231. Inside the gate trenches 206, the gate electrodes 208 are disposed via the gate insulating films 207, respectively. The gate electrodes 208 are electrically insulated from the source electrode by an interlayer insulating film 211. The first and second p⁺-type regions 231 and 232 and n-type current spreading regions 233 are diffused regions formed by ion implantation in an n-type epitaxial layer constituting the n-type drift region 202, and are selectively disposed between the p-type base region 203 and the n--type drift region 202, at positions deeper toward the n⁺-type drain region than are bottoms of the gate trenches 206.

The first p⁺-type regions 231 are disposed apart from the p-type base region 203, at positions facing the bottoms of the gate trenches 206 and at portions substantially in the center between the gate trenches 206 adjacent to each other (i.e. directly below the p⁺⁺-type contact regions 205), and the first p⁺-type regions 231 extend in the first direction X and have substantially the same length as the longitudinal length of the gate trenches 6. The first p⁺-type regions 231 adjacent to each other are partially connected to each other at a portion not depicted. The first p⁺-type regions 231 directly below the gate trenches 206 are in contact with the gate insulating films 207 along the bottom of each of the gate trenches 206. The first p⁺-type regions 231 directly below the p⁺⁺-type contact regions 205 are disposed apart from the gate trenches 206. The width in the second direction Y of the first p⁺-type regions 231 directly below the gate trenches 206 (TBP width W_TBP) is substantially the same as the trench width W_Trench.

The second p⁺-type regions 232 are disposed between the gate trenches 206 adjacent to each other; the second p⁺-type regions 232 are apart from the gate trenches 206 and in contact with the p-type base region 203. The second p⁺-type regions 232 extend between the first p⁺-type regions 231 directly below the p⁺⁺-type contact regions 205 and the p-type base region 203, in the first direction X and have a length substantially equal to the longitudinal length of the gate trenches 6. The second p⁺-type regions 232 electrically connect the first p⁺-type regions 231 and the p-type base region 203. Each of the n-type current spreading regions 233 has an upper surface in contact with the p-type base region 203 and a lower surface in contact with the n-type drift region 202; the n-type current spreading regions 233 are in contact with the first and second p⁺-type regions 231 and 232 and the gate insulating films 207 along the sidewalls of the gate trenches 206, in the second direction Y. Each of the n-type current spreading regions 233 is divided into an upper part 233a and a lower part 233b formed in multiple stages.

A depth of each of the first p⁺-type regions 231 in the first comparison example is the same for the first p⁺-type regions 231 directly below the p⁺⁺-type contact regions 205 and the first p⁺-type regions 231 directly below the gate trenches 206. In the second comparison example, only a depth d201 of the first p⁺-type regions 231 directly below the gate trenches 206 is made deeper than in the first comparison example. The depth d201 of the first p⁺-type regions 231 directly below the gate trenches 206 is a distance in the depth direction Z from the bottoms of the gate trenches 206 (upper surface of each of the first p⁺-type regions 231) to a lower surface of each of the first p⁺-type regions 231 and corresponds to a thickness of each of the first p⁺-type regions 231 directly below the gate trenches 206. The first and second comparison examples are the same except for the depth d201 of the first p⁺-type regions 231 directly below the gate trenches 206. The trench width W_Trench is set to be 0.8 μm.

In the first and second comparison examples, the TBP width W_TBP was changed in various ways and the results of simulating the breakdown voltage BVdss, the gate threshold voltage Vth, the on-resistance RonA, and the electric field strength versus the ratio of the TBP width W_TBP to the trench width W_Trench are respectively depicted in FIGS. 18 to 21. FIGS. 18 to 21 respectively depict approximation curves 241 to 244 of each characteristic based on multiple simulation results for the first comparison example. While FIGS. 18 to 21 respectively depict one simulation result 251 to 254 for the second comparison example, the inventors have confirmed that the approximation curves for each characteristic for the second comparison example included the simulation results 251 to 254, respectively, and are approximation curves that progress substantially parallel to the approximation curves 241 to 244 of the first comparison example.

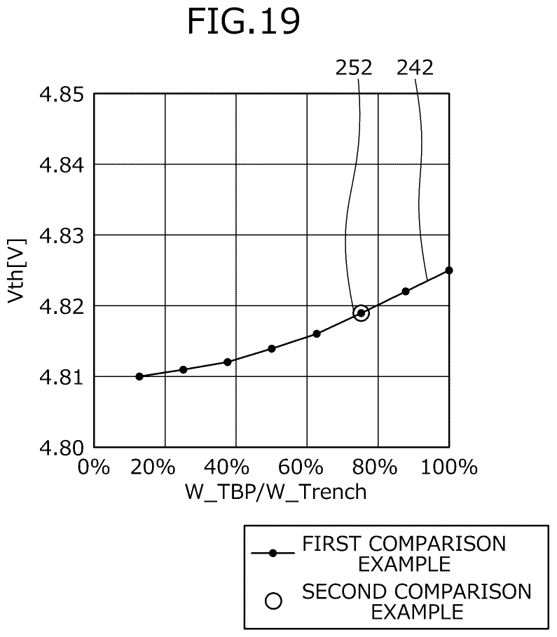

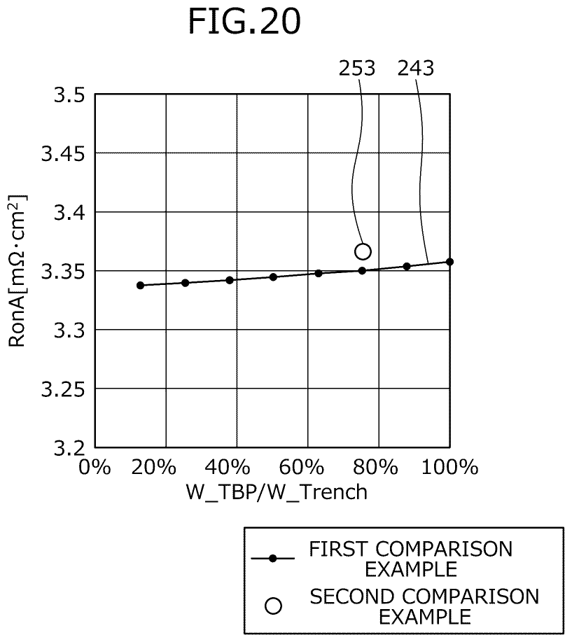

The results depicted in FIG. 18 confirmed that the wider is the TBP width W_TBP, the higher is the breakdown voltage BVdss. It was also confirmed that the deeper is the depth d201 of the first p⁺-type regions 231 directly below the gate trenches 206, the higher is the breakdown voltage BVdss. By increasing the breakdown voltage BVdss, the breakdown voltage may be improved. The results depicted in FIGS. 19 and 20 confirmed that the gate threshold voltage Vth and the on-resistance RonA are nearly independent of the TBP width W_TBP and the depth d201 of the first p⁺-type regions 231 directly below the gate trenches 206. Therefore, even in a case that the width w211 (Fin width) between the gate trenches 206 adjacent to each other is reduced to obtain the effect of the FinFET structure, the TBP width W_TBP contributes to the breakdown voltage and does not adversely affect the effect of the FinFET structure (reduction of the on-resistance).

The results depicted in FIG. 21 confirmed that the wider is the TBP width W_TBP, the smaller the electric field strength at the bottoms of the gate trenches 206 becomes. In order to set the electric field strength at the bottoms of the gate trenches 206 to, for example, 3 MV/cm or less at which dielectric breakdown of the gate insulating films 207 in SiC does not occur, setting the TBP width W_TBP to about 75% to 100% of the trench width W_Trench is preferable. By reducing the electric field strength at the bottoms of the gate trenches 206, the breakdown voltage may be improved. Even when the TBP width W_TBP is within the range above, the narrower is the TBP width W_TBP, the lower is the breakdown voltage BVdss (see FIG. 18), thereby decreasing the breakdown voltage. In a case where the effect of the FinFET structure is obtained, the electric field strength at the bottoms of the gate trenches 206 increases, thereby decreasing the breakdown voltage.

Therefore, by appropriately increasing the depth d201 of the first p⁺-type regions 231 directly below the gate trenches 206, increasing the breakdown voltage BVdss (see FIG. 18), and improving the breakdown voltage, a specified breakdown voltage may be obtained. Specifically, in a case where the width w211 between the gate trenches 206 adjacent to each other is set to the Fin width, which is less than the trench width W_Trench, to obtain the effect of the FinFET structure, the inventors have confirmed that the depth d201 of the first p⁺-type regions 231 directly below the gate trenches 206 is, preferably, at least equal to the Fin width and approximately 0.8 μm or greater. Thus, the breakdown voltage BVdss becomes, for example, 1200 V or higher (see FIG. 18), making avalanche breakdown less likely to occur, thereby obtaining the specified breakdown voltage.

While not depicted, the silicon carbide semiconductor devices 40 and 50 according to the second and third embodiments have the same characteristics as those depicted in FIGS. 18 to 21.

As described above, the present disclosure is not limited to the above-mentioned embodiments, and various modifications may be made without departing from the spirit of the present disclosure. For example, in each of the first to fourth embodiments, similar to the fifth embodiment, the thickness of portions of the gate insulating films along the bottoms of the gate trenches may be made thicker than the thickness of portions of the gate insulating films along the sidewalls of the gate trenches. Instead of forming the n⁺-type source regions by ion implantation, the n⁺-type source regions may be formed by an n⁺-type epitaxial layer. In this case, the surface of the n⁺-type epitaxial layer constituting the n⁺-type source regions is the front surface of the semiconductor substrate. Although the first conductivity type is an n-type and the second conductivity type is a p-type in each embodiment, the present disclosure is similarly implemented when the first conductivity type is a p-type and the second conductivity type is an n-type.

According to the silicon carbide semiconductor device and the method of manufacturing the silicon carbide semiconductor device according to the present disclosure, the silicon carbide semiconductor device has the trench gate structure in which unit cells of the FinFET structure are arranged and achieves an effect of enabling improvement of the breakdown voltage.

As described above, the silicon carbide semiconductor device and the method of manufacturing the silicon carbide semiconductor device according to the present disclosure are useful for power semiconductor devices used in power converting equipment, power supply devices for various industrial machines, and the like.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A silicon carbide semiconductor device, comprising:
a semiconductor substrate containing silicon carbide and having a first main surface and a second main surface opposite to each other;
a first semiconductor region of a first conductivity type, provided in the semiconductor substrate;
a plurality of second semiconductor regions of a second conductivity type, provided in the semiconductor substrate between the first main surface of the semiconductor substrate and the first semiconductor region;
a plurality of third semiconductor regions of the first conductivity type, selectively provided in the semiconductor substrate between the first main surface of the semiconductor substrate and the plurality of second semiconductor regions;
a plurality of fourth semiconductor regions of the second conductivity type, selectively provided in the semiconductor substrate between the first main surface of the semiconductor substrate and the plurality of second semiconductor regions, the plurality of fourth semiconductor regions having a dopant concentration higher than a dopant concentration of the plurality of second semiconductor regions;
a plurality of gate trenches penetrating through the plurality of fourth semiconductor regions, the plurality of third semiconductor regions, and the plurality of second semiconductor regions, each of the plurality of gate trenches reaching the first semiconductor region;
a plurality of first high concentration regions of the second conductivity type, provided at positions facing bottoms of the plurality of gate trenches, the plurality of first high concentration regions having a dopant concentration higher than the dopant concentration of the plurality of second semiconductor regions;
a plurality of gate electrodes disposed in the plurality of gate trenches via a plurality of gate insulating films, respectively;
a first electrode electrically connected to the plurality of fourth semiconductor regions, the plurality of third semiconductor regions, the plurality of second semiconductor regions, and the plurality of first high concentration regions; and
a second electrode disposed on the second main surface of the semiconductor substrate, wherein
the plurality of gate trenches have, between any adjacent two thereof, one of the plurality of second semiconductor regions formed therein;
the silicon carbide semiconductor device has a double-gate structure in which, for each adjacent two of the plurality of gate trenches, a channel is formed over an entire area of the second semiconductor region therebetween, and is sandwiched from two sides thereof by said each adjacent two of the plurality of gate trenches; and
each of the plurality of first high concentration regions has a width that is no more than a width of each of the plurality of gate trenches, but is more than a distance between any adjacent two of the plurality of gate trenches.

2. The silicon carbide semiconductor device according to claim 1, wherein the width of each of the plurality of first high concentration regions is no less than 75% of the width of each of the plurality of gate trenches.

3. The silicon carbide semiconductor device according to claim 1, wherein the plurality of first high concentration regions has a depth at least equal to the distance between any adjacent two of the plurality of gate trenches.

4. The silicon carbide semiconductor device according to claim 1, wherein
the plurality of gate trenches extends linearly in a first direction parallel to the first main surface of the semiconductor substrate, and
a subset of the plurality of third semiconductor regions and a subset of the plurality of fourth semiconductor regions are disposed between any adjacent two of the plurality of trenches, said subset of the third semiconductor regions and said subset of fourth semiconductor regions repeatedly alternating with each other in the first direction.

5. The silicon carbide semiconductor device according to claim 4, comprising:
a plurality of second high concentration regions of the second conductivity type, each provided between adjacent two of the plurality of gate trenches, the plurality of second high concentration regions being in contact with the plurality of second semiconductor regions and facing the plurality of fourth semiconductor regions in a depth direction of the silicon carbide semiconductor device, respectively, the plurality of second high concentration regions having a dopant concentration higher than the dopant concentration of the plurality of second semiconductor regions, wherein
the plurality of first high concentration regions is electrically connected to the plurality of second semiconductor regions via the plurality of second high concentration regions.

6. The silicon carbide semiconductor device according to claim 5, wherein
of the plurality of first high concentration regions, ones adjacent to one another in a second direction, which is parallel to the first main surface of the semiconductor substrate and orthogonal to the first direction, are partially connected at locations facing the plurality of second high concentration regions in the depth direction, and
the plurality of second high concentration regions is in contact with the plurality of first high concentration regions in the depth direction.

7. The silicon carbide semiconductor device according to claim 5, wherein
the plurality of second high concentration regions reaches a depth closer to the second electrode than are the bottoms of the plurality of gate trenches, and
the plurality of second high concentration regions is in contact with the plurality of first high concentration regions in a second direction, which is parallel to the first main surface of the semiconductor substrate and orthogonal to the first direction.

8. The silicon carbide semiconductor device according to claim 1, wherein
each of the plurality of first high concentration regions has a portion facing one of the plurality of fourth semiconductor regions in a depth direction of the silicon carbide semiconductor device, the portion extending along a sidewall of one of the plurality of gate trenches to the first electrode and being in contact with one of the plurality of second semiconductor regions.

9. The silicon carbide semiconductor device according to claim 5, wherein
the plurality of first high concentration regions is not provided at positions facing the plurality of third semiconductor regions in the depth direction.

10. The silicon carbide semiconductor device according to claim 5, wherein
the plurality of second high concentration regions is not provided at positions facing the plurality of third semiconductor regions in the depth direction.

11. The silicon carbide semiconductor device according to claim 1, comprising:
a fifth semiconductor region of the first conductivity type, provided in the semiconductor substrate between, and in contact with, the first semiconductor region and the plurality of second semiconductor regions, the fifth semiconductor region and the plurality of first high concentration regions terminating at a same depth, the fifth semiconductor region having a dopant concentration higher than a dopant concentration of the first semiconductor region.

12. A silicon carbide semiconductor device, comprising:
a semiconductor substrate containing silicon carbide and having a first main surface and a second main surface opposite to each other;
a first semiconductor region of a first conductivity type, provided in the semiconductor substrate;
a plurality of second semiconductor regions of a second conductivity type, provided in the semiconductor substrate between the first main surface of the semiconductor substrate and the first semiconductor region;
a plurality of third semiconductor regions of the first conductivity type, selectively provided in the semiconductor substrate between the first main surface of the semiconductor substrate and the plurality of second semiconductor regions;
a plurality of fourth semiconductor regions of the second conductivity type, selectively provided in the semiconductor substrate between the first main surface of the semiconductor substrate and the plurality of second semiconductor regions, the plurality of fourth semiconductor regions having a dopant concentration higher than a dopant concentration of the plurality of second semiconductor regions;
a plurality of gate trenches penetrating through the plurality of fourth semiconductor regions, the plurality of third semiconductor regions, and the plurality of second semiconductor regions, each of the plurality of gate trenches reaching the first semiconductor region;
a plurality of first high concentration regions of the second conductivity type, provided at positions facing bottoms of the plurality of gate trenches, the plurality of first high concentration regions having a dopant concentration higher than the dopant concentration of the plurality of second semiconductor regions;
a plurality of second high concentration regions of the second conductivity type, each provided between adjacent two of the plurality of gate trenches, the plurality of second high concentration regions being in contact with the plurality of second semiconductor regions and having a dopant concentration higher than the dopant concentration of the plurality of second semiconductor regions;
a plurality of gate electrodes provided in the plurality of gate trenches via a plurality of gate insulating films, respectively;
a first electrode electrically connected to the plurality of fourth semiconductor regions, the plurality of third semiconductor regions, the plurality of second semiconductor regions, the plurality of first high concentration regions, and the plurality of second high concentration regions; and
a second electrode disposed on the second main surface of the semiconductor substrate, wherein
the plurality of gate trenches extends linearly in a first direction parallel to the first main surface of the semiconductor substrate;
the plurality of gate trenches have, between any adjacent two thereof, one of the plurality of second semiconductor regions formed therein;
the silicon carbide semiconductor device has a double-gate structure in which, for each adjacent two of the plurality of gate trenches, a channel is formed over an entire area of the second semiconductor region therebetween, and is sandwiched from two sides thereof by said each adjacent two of the plurality of gate trenches;
a subset of the plurality of third semiconductor regions and a subset of the plurality of fourth semiconductor regions are provided between adjacent two of the plurality of gate trenches, said subset of the third semiconductor regions and said subset of fourth semiconductor regions repeatedly alternate with each other in the first direction;
the plurality of second high concentration regions is disposed facing the plurality of fourth semiconductor regions in a depth direction of the silicon carbide semiconductor device; and
the plurality of first high concentration regions is electrically connected to the plurality of second semiconductor regions via the plurality of second high concentration regions.

13. The silicon carbide semiconductor device according to claim 12, wherein
the plurality of first high concentration regions is not provided at positions facing the plurality of third semiconductor regions in the depth direction.

14. The silicon carbide semiconductor device according to claim 12, wherein
the plurality of second high concentration regions is not provided at positions facing the plurality of third semiconductor regions in the depth direction.

15. The silicon carbide semiconductor device according to claim 12, comprising:
a fifth semiconductor region of the first conductivity type, provided in the semiconductor substrate between, and in contact with, the first semiconductor region and the plurality of second semiconductor regions, the fifth semiconductor region and the plurality of first high concentration regions terminating at a same depth, the fifth semiconductor region having a dopant concentration higher than a dopant concentration of the first semiconductor region.

16. A silicon carbide semiconductor device, comprising:
a semiconductor substrate containing silicon carbide and having a first main surface and a second main surface opposite to each other;
a first semiconductor region of a first conductivity type, provided in the semiconductor substrate;
a plurality of second semiconductor regions of a second conductivity type, provided in the semiconductor substrate between the first main surface of the semiconductor substrate and the first semiconductor region;
a plurality of third semiconductor regions of the first conductivity type, selectively provided in the semiconductor substrate between the first main surface of the semiconductor substrate and the plurality of second semiconductor regions;
a plurality of fourth semiconductor regions of the second conductivity type, selectively provided in the semiconductor substrate between the first main surface of the semiconductor substrate and the plurality of second semiconductor regions, the plurality of fourth semiconductor regions having a dopant concentration higher than a dopant concentration of the plurality of second semiconductor regions;
a plurality of gate trenches penetrating through the plurality of fourth semiconductor regions, the plurality of third semiconductor regions, and the plurality of second semiconductor regions, each of the plurality of gate trenches reaching the first semiconductor region;
a plurality of first high concentration regions of the second conductivity type, selectively provided at positions facing bottoms of the plurality of gate trenches, the plurality of first high concentration regions having a dopant concentration higher than the dopant concentration of the plurality of second semiconductor regions;
a plurality of gate electrodes provided in the plurality of gate trenches via a plurality of gate insulating films, respectively;
a first electrode electrically connected to the plurality of fourth semiconductor regions, the plurality of third semiconductor regions, the plurality of second semiconductor regions, and the plurality of first high concentration regions; and
a second electrode disposed on the second main surface of the semiconductor substrate, wherein
the plurality of gate trenches extends linearly in a first direction parallel to the first main surface of the semiconductor substrate;
the plurality of gate trenches have, between any adjacent two thereof, one of the plurality of second semiconductor regions formed therein;
the silicon carbide semiconductor device has a double-gate structure in which, for each adjacent two of the plurality of gate trenches, a channel is formed over an entire area of the second semiconductor region therebetween, and is sandwiched from two sides thereof by said each adjacent two of the plurality of gate trenches;
a subset of the plurality of third semiconductor regions and a subset of the plurality of fourth semiconductor regions are disposed between adjacent two of the plurality of gate trenches, said subset of the third semiconductor regions and said subset of fourth semiconductor regions repeatedly alternative with each other in the first direction; and
each of the plurality of first high concentration regions has a portion facing one of the plurality of fourth semiconductor regions in a depth direction of the silicon carbide semiconductor device, the portion extending along a sidewall of one of the plurality of gate trenches to the first electrode and being in contact with one of the plurality of second semiconductor regions.

17. The silicon carbide semiconductor device according to claim 16, wherein
the plurality of first high concentration regions is not provided at positions facing the plurality of third semiconductor regions in the depth direction.

18. The silicon carbide semiconductor device according to claim 16, comprising:
a fifth semiconductor region of the first conductivity type, provided in the semiconductor substrate between, and in contact, with the first semiconductor region and the plurality of second semiconductor regions, the fifth semiconductor region and the plurality of first high concentration regions terminating at a same depth, the fifth semiconductor region having a dopant concentration higher than a dopant concentration of the first semiconductor region.

19. A silicon carbide semiconductor device, comprising:
a semiconductor substrate containing silicon carbide and having a first main surface and a second main surface opposite to each other;
a first semiconductor region of a first conductivity type, provided in the semiconductor substrate;
a plurality of second semiconductor regions of a second conductivity type, provided in the semiconductor substrate between the first main surface of the semiconductor substrate and the first semiconductor region;
a plurality of third semiconductor regions of the first conductivity type, selectively provided in the semiconductor substrate between the first main surface of the semiconductor substrate and the plurality of second semiconductor regions;
a plurality of fourth semiconductor regions of the second conductivity type, selectively provided in the semiconductor substrate between the first main surface of the semiconductor substrate and the plurality of second semiconductor regions, the plurality of fourth semiconductor regions having a dopant concentration higher than a dopant concentration of the plurality of second semiconductor regions;
a plurality of gate trenches penetrating through the plurality of fourth semiconductor regions, the plurality of third semiconductor regions, and the plurality of second semiconductor regions, each of the plurality of gate trenches reaching the first semiconductor region;
a plurality of gate insulating films provided along inner walls of the plurality of gate trenches, respectively;
a plurality of gate electrodes provided in the plurality of gate trenches, on the plurality of gate insulating films, respectively;
a first electrode electrically connected to the plurality of fourth semiconductor regions, the plurality of third semiconductor regions, and the plurality of second semiconductor regions; and
a second electrode provided on the second main surface of the semiconductor substrate, wherein
the plurality of gate trenches have, between any adjacent two thereof, one of the plurality of second semiconductor regions formed therein;
the silicon carbide semiconductor device has a double-gate structure in which, for each adjacent two of the plurality of gate trenches, a channel is formed over an entire area of the second semiconductor region therebetween, and is sandwiched from two sides thereof by said each adjacent two of the plurality of gate trenches; and
for each of the plurality of gate trenches, the one of the plurality of gate insulating films formed therein has a first portion of a first thickness at a bottom of said each gate trench and a second portion of a second thickness along a sidewall of said each gate trench, the first thickness being greater than the second thickness and greater than a distance between any adjacent two of the plurality of gate trenches.

20. The silicon carbide semiconductor device according to claim 19, comprising:
a fifth semiconductor region of the first conductivity type, provided in the semiconductor substrate between, and in contact, with the first semiconductor region and the plurality of second semiconductor regions, the fifth semiconductor region terminating closer to the second electrode than are bottoms of the plurality of gate trenches, the fifth semiconductor region having a dopant concentration higher than a dopant concentration of the first semiconductor region.
